(19) United States
(12) Patent Application Publication
(10) Pub. No.: US 2026/0171344 A1
(43) Pub. Date: Jun. 18, 2026

(54) ION IMPLANTATION DEVICE

(71) Applicant: Sumitomo Heavy Industries Ion Technology Co., Ltd., Tokyo (JP)

(72) Inventors: Haruka SASAKI, Saijo-shi, Ehime (JP); Takaaki MATSUMOTO, Saijo-shi, Ehime (JP); Yukio KUMATA, Saijo-shi, Ehime (JP)

(73) Assignee: Sumitomo Heavy Industries Ion Technology Co., Ltd., Tokyo (JP)

(21) Appl. No.: 19/418,104

(22) Filed: Dec. 12, 2025

(30) Foreign Application Priority Data
Dec. 13, 2024 (JP) 2024-218832

(51) Int. Cl. H01J 37/16; H01J 37/04; H01J 37/317

(52) U.S. Cl. CPC H01J 37/16; H01J 37/04; H01J 37/3171; H01J 2237/002; H01J 2237/0266; H01J 2237/04735; H01J 2237/04756

(57) ABSTRACT

Provided is a technology that enables at least some of a plurality of resonators, which are provided in an ion implanter, to have a simpler configuration. An ion implanter includes a linear acceleration unit that adjusts energy of ions, the linear acceleration unit includes a plurality of resonators, each of the plurality of resonators includes: an electrode for generating a radio-frequency electric field, the electrode being configured to accelerate or decelerate the ions by generating the radio-frequency electric field; a coil; a stem that connects the electrode and the coil; and a housing that surrounds the coil, and at least one of the plurality of resonators is configured, such that a gas for cooling at least the coil is present inside the housing, and has a configuration for generating a flow of the gas for promoting the cooling of at least the coil in a vicinity of the coil.

### CROSS-REFERENCE TO RELATED APPLICATION

The present application claims priority under 35 U.S.C. § 119(a) to Japanese Patent Application No. 2024-218832 filed on Dec. 13, 2024.

### BACKGROUND

### Field

The present invention relates to an ion implanter.

### Description of Related Art

In a semiconductor manufacturing process, an ion implantation process of implanting ions into a semiconductor wafer is performed. An ion implanter used in the ion implantation process is required to acquire an ion beam having desired characteristics (such as ion species, energy, a beam current, a beam size, a beam orbit center axis angle, the degree of beam parallelism, and a beam divergence angle) before performing ion implantation into the wafer. In a case where ions having relatively high energy (for example, 1 MeV or more) are implanted into the wafer, some ion implanters are provided with a linear acceleration unit using a radio-frequency electric field, and a plurality of resonators are arranged in the linear acceleration unit.

For example, Japanese Translation of PCT Application No. 2003-535439 discloses an ion implanter including an ion accelerator that accelerates an ion beam. The ion implanter described in Japanese Translation of PCT Application No. 2003-535439 includes a resonant coil for controlling a radio-frequency resonant state. In addition, the ion implanter described in Japanese Translation of PCT Application No. 2003-535439 has a configuration in which cooling water is circulated in the resonant coil of a resonator.

### SUMMARY

However, in the ion implanter described in Japanese Translation of PCT Application No. 2003-535439, the resonant coil can be cooled by circulating the cooling water in the coil, but a configuration of the resonator becomes relatively complicated, and it is considered that there is room for improvement. For example, in an ion implanter provided with a plurality of resonators, it is considered that, among the resonators, a resonator that is relatively resistant to temperature rise can have a simpler cooling configuration.

Therefore, an object of the present disclosure is to provide a technology that enables at least some of a plurality of resonators provided in an ion implanter to have a simpler configuration.

An aspect of the present disclosure is an ion implanter including a linear acceleration unit that adjusts energy of ions, wherein the linear acceleration unit includes a plurality of resonators, each of the plurality of resonators includes: an electrode for generating a radio-frequency electric field, the electrode being configured to accelerate or decelerate the ions by generating the radio-frequency electric field; a coil; a stem that connects the electrode and the coil; and a housing that surrounds the coil, and at least one of the plurality of resonators is configured, such that a gas for cooling at least the coil is present inside the housing, and has a configuration for generating a flow of the gas for promoting the cooling of at least the coil in a vicinity of the coil.

As described above, in the resonator of the conventional ion implanter, for example, since the cooling water is circulated by providing the cooling water supply path, the circulation path, and the like, the configuration of the resonator may be relatively complicated. According to one aspect of the present disclosure, with the above configuration, for example, the flow of the gas for prompting the cooling of the coil is generated without providing the configuration for circulating the cooling water, so that the ion implanter can have a simpler configuration. Therefore, for example, it is possible to reduce the size and cost of the ion implanter.

Note that any combinations of the above constituent elements and the constituent elements and expressions of the present invention that are mutually exchanged among methods, devices, systems, and the like are also effective as aspects of the present invention.

### BRIEF DESCRIPTION OF DRAWINGS

FIG. 1 is a top view illustrating a schematic configuration of an ion implanter 100 according to the present embodiment.

FIG. 2 is a view schematically illustrating a schematic configuration of a linear acceleration device 122a.

FIG. 3A is a cross-sectional view illustrating a schematic configuration of an electrostatic quadrupole lens.

FIG. 3B is a cross-sectional view illustrating a schematic configuration of an electrostatic quadrupole lens.

FIG. 4A is a diagram schematically illustrating a power system of a resonator 210.

FIG. 4B is a diagram schematically illustrating an equivalent circuit of the power system of the resonator 210.

FIG. 5A is a side view of the resonator 210 when viewed in a beam traveling direction.

FIG. 5B is a side view of the resonator 210 when viewed in a direction perpendicular to the beam traveling direction.

FIG. 5C is a cross-sectional view of the resonator 210.

FIG. 6 is an internal transparent perspective view of a resonator 210A.

FIG. 7A is a perspective view of the vicinity of a lid portion 212a of the resonator 210A.

FIG. 7B is a perspective view of the vicinity of a bottom portion 212b of the resonator 210A.

FIG. 8A is a perspective view of a housing 212 of a resonator 210B.

FIG. 8B is a perspective view of an interior of the housing 212 of the resonator 210B.

FIG. 9 is a perspective view of a part of a resonator 210C.

FIG. 10A is an internal transparent perspective view of a resonator 210D.

FIG. 10B is a perspective view of a heat sink 254.

FIG. 11 is a view schematically illustrating the resonator 210C and an air cooler 270.

FIG. 12A is a perspective view of a resonator 210E.

FIG. 12B is a longitudinal sectional perspective view of the resonator 210E.

FIG. 13 is a perspective view of the vicinity of a lid portion 212a of a resonator 210F.

FIG. 14A is a view illustrating a simulation result of an airflow in a housing 212 of the resonator 210E.

FIG. 14B is a view illustrating a simulation result of an airflow in a housing 212 of a resonator 210G.

FIG. 15A is a perspective view of a vacuum chamber 240.

FIG. 15B is a perspective view of the vacuum chamber 240.

### DETAILED DESCRIPTION

Hereinafter, embodiments of the present disclosure will be described with reference to the accompanying drawings. In order to facilitate understanding of the description, the same constituent elements in the drawings are denoted by the same reference numerals as much as possible, and redundant description will be omitted or simplified.

In addition, an X axis, a Y axis, and a Z axis may be illustrated in each drawing. The X axis, the Y axis, and the Z axis form a right-handed three-dimensional orthogonal coordinate system. Hereinafter, an arrow direction along the X axis may be referred to as a +X-axis direction or a +X direction, a direction opposite to the arrow may be referred to as a −X-axis direction or a −X direction, and the same applies to the other axes. Note that a +Z-axis direction or a +Z direction and a −Z-axis direction or a −Z direction may be referred to as an “upper side” and a “lower side”, respectively. In addition, a plane orthogonal to the X axis, the Y axis, or the Z axis may be referred to as a YZ plane, a ZX plane, or an XY plane. A Z-axis direction may be referred to as a “up-down direction”. The terms “upper side”, “lower side”, and “up-down direction” are merely terms indicating a relative positional relationship in the drawings, and are not terms that determine a direction based on a vertical direction.

In addition, unless specifically described, the dimensions and the like of the constituent elements illustrated in each drawing may be different from the actual dimensions in order to facilitate understanding of the description.

In the present specification, the term “connection” includes not only physical connection but also electrical connection, and includes not only direct connection but also indirect connection made via another object unless otherwise specified.

In the present specification, the expression “formed above” includes not only a case of being formed directly above, but also a case of being formed above with another object interposed unless otherwise specified. The same applies to a case of “being formed below” and the like.

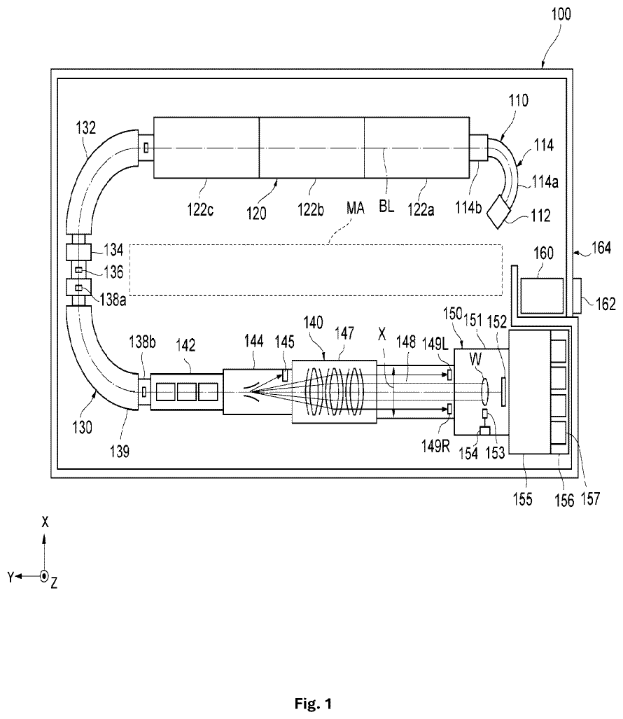

First, an outline of an embodiment according to the present disclosure will be described with reference to FIG. 1. The present embodiment relates to a high-energy ion implanter (an ion implanter 100 illustrated in FIG. 1). The ion implanter 100 accelerates an ion beam generated by an ion source by a radio-frequency linear acceleration device (beam acceleration unit 120), transports a high-energy ion beam obtained by the acceleration to an object to be processed (for example, a substrate or a wafer) along a beamline, and implants ions into the object to be processed.

The expression “high energy” in the present embodiment refers to an ion beam having a beam energy of 1 MeV or more, 4 MeV or more, or 10 MeV or more. In high-energy ion implantation, since desired dopant ions are implanted into a wafer surface with relatively high energy, desired dopant elements can be implanted into a deeper region (for example, a depth of 5 μm or more) of the wafer surface. An application of the high-energy ion implantation is, for example, to form a P-type region and/or an N-type region in manufacturing a semiconductor device such as an image sensor.

In the present embodiment, ions used for an ion implantation process may be, for example, positive ions, and specifically, may be at least one of boron ions, phosphorus ions, and arsenic ions. A charge state of the ions to be used may be, for example, monovalent (+1) to pentavalent(+5). In addition, energy of the ions to be used may be, for example, 10 keV or more and less than 1 MeV, and in a case where the energy of the ions is, for example, 10 keV or more and less than 1 MeV, a beam current of the ion beam formed by such ions may be, for example, 1 uA or more and 10 mA or less.

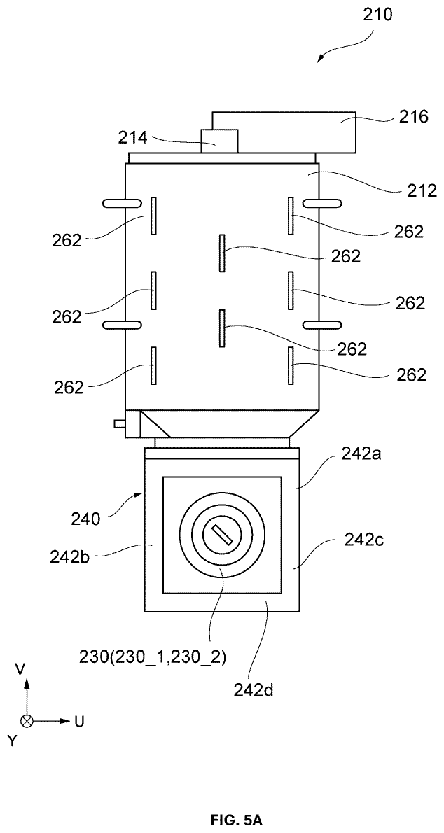

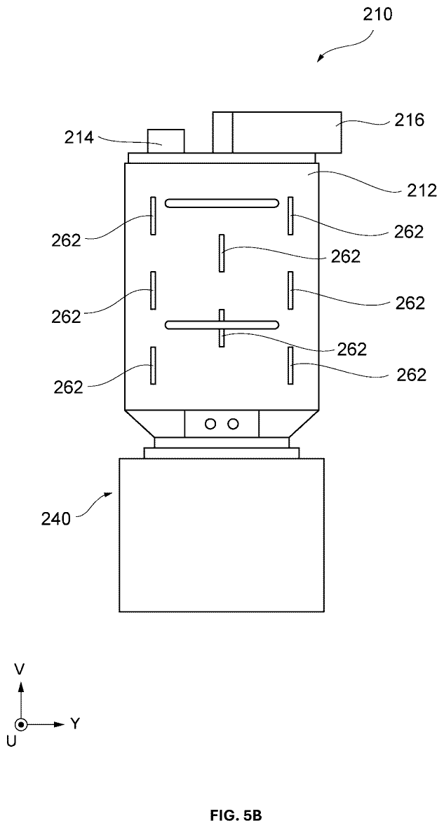

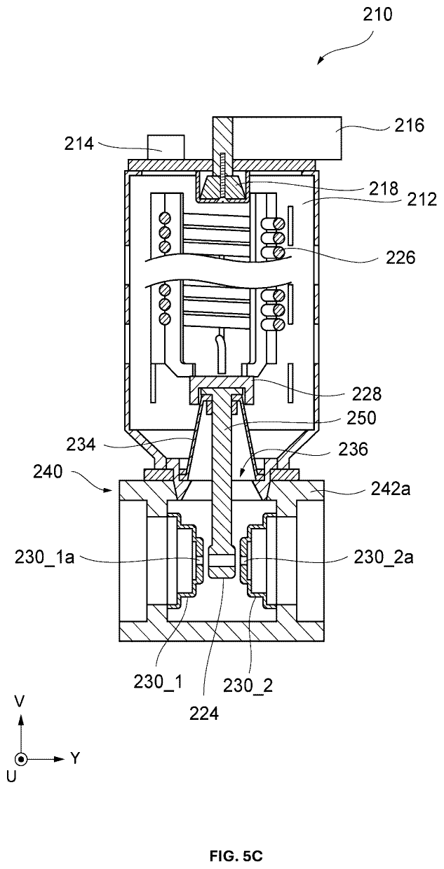

The ion implanter 100 (FIG. 1) according to the embodiment of the present disclosure is the ion implanter 100 including the linear acceleration unit (beam acceleration unit 120) that adjusts the energy of the ions, in which the linear acceleration unit 120 includes a plurality of resonators, and each of the plurality of resonators is configured to accelerate or decelerate the ions by generating a radio-frequency electric field, and includes an electrode (resonator electrode) for generating the radio-frequency electric field, a coil (resonant coil), a stem that connects the electrode and the coil, and a housing that surrounds the coil. At least one of the plurality of resonators is configured such that at least a gas for cooling the coil is present inside the housing, and has a configuration for generating a flow of the gas for promoting the cooling of at least the coil in the vicinity of the coil. The configuration of the resonator according to the present embodiment is described below with reference to FIG. 5A and the like.

In the ion implanter 100 of the present embodiment, at least some of the plurality of resonators are configured such that a gas for cooling at least the coil is present inside the housing, and a configuration for generating a flow of the gas for promoting the cooling of at least the coil is provided in the vicinity of the coil, whereby the inside of the resonator can be effectively cooled.

As described above, in the resonator of the conventional ion implanter, for example, the resonant coil can be cooled by circulating cooling water in the resonant coil. However, since a cooling water supply path, a cooling water circulation path, and the like are provided, the configuration of the resonator may be relatively complicated.

In the ion implanter 100 of the embodiment of the present disclosure, with the above configuration, for example, the flow of the gas for prompting the cooling of the coil is generated without providing the configuration for circulating the cooling water, so that the ion implanter can have a simpler configuration. Therefore, for example, it is possible to reduce the size and cost of the ion implanter.

The above configuration of the resonator of the ion implanter of the present embodiment can be effectively applied to, for example, a resonator that forms a relatively low-voltage resonant state among the plurality of resonators. In the resonator, sulfur hexafluoride (SF6) may be supplied to the periphery of the coil or the like in order to suppress discharge. For example, the first few (e.g., two) resonators among the plurality of resonators arranged in series are used to generate a bunched beam, and the bunched beam is accelerated at the remaining subsequent resonators. Since the bunched beam can be formed at a relatively low voltage, the first few resonators can operate at a relatively low voltage. In a case where the resonator is used at a relatively low voltage, the occurrence of discharge is suppressed, so that sulfur hexafluoride or the like as described above may not be supplied.

In such a resonator, a gas capable of cooling the coil or the like can be present in place of a discharge suppressing gas such as sulfur hexafluoride in the housing, and the configuration of the resonator of the ion implanter of the present embodiment can be effectively applied.

Hereinafter, a schematic configuration of the ion implanter 100 according to the embodiment of the present disclosure will be described with reference to FIG. 1. FIG. 1 is a top view schematically illustrating the ion implanter 100 according to the present embodiment. The ion implanter 100 includes a beam generation unit 110, the beam acceleration unit 120, a beam deflection unit 130, a beam transport unit 140, and a substrate transfer and processing unit 150.

The beam generation unit 110 includes an ion source 112 and a mass spectrometer 114. In the beam generation unit 110, the ion beam is extracted from the ion source 112, and the extracted ion beam is subjected to mass spectrometry by the mass spectrometer 114. The mass spectrometer 114 includes a mass spectrometry magnet 114a and a mass spectrometry slit 114b. The mass spectrometry slit 114b is disposed downstream of the mass spectrometry magnet 114a. As a result of the mass spectrometry performed by the mass spectrometer 114, only ion species necessary for implantation are selected, and the ion beam of the selected ion species is guided to the next beam acceleration unit 120.

The beam acceleration unit 120 includes a plurality of linear acceleration devices 122 (first linear acceleration device 122a, second linear acceleration device 122b, and third linear acceleration device 122c) that accelerate the ion beam, and forms a linearly extending portion of a beamline BL. Each of the plurality of linear acceleration devices 122a to 122c includes one or more radio-frequency acceleration units, and causes a radio-frequency (RF) electric field to act on the ion beam to accelerate the ion beam.

In the present embodiment, as illustrated in FIG. 1, three linear acceleration devices 122a to 122c are provided.

The first linear acceleration device 122a is provided at an upper stage of the beam acceleration unit 120 and includes a plurality of stages (for example, 5 to 15 stages) of radio-frequency acceleration units. The first linear acceleration device 122a performs “bunching” to align a continuous beam (DC beam) output from the beam generation unit 110 with a specific acceleration phase, and accelerates the ion beam to an energy of, for example, about 1 MeV.

The second linear acceleration device 122b is provided at a middle stage of the beam acceleration unit 120 and includes a plurality of stages (for example, 5 to 15 stages) of radio-frequency acceleration units. The second linear acceleration device 122b accelerates the ion beam output from the first linear acceleration device 122 a to an energy of, for example, about 2 to 3 MeV.

The third linear acceleration device 122c is provided at a lower stage of the beam acceleration unit 120 and includes a plurality of stages (for example, 5 to 15 stages) of radio-frequency acceleration units. The third linear acceleration device 122c is configured to accelerate the ion beam output from the second linear acceleration device 122b to a high energy of, for example, 4 MeV or more.

The high-energy ion beam output from the beam acceleration unit 120 has an energy distribution in a predetermined range. Therefore, for the purpose of irradiating the wafer with the high-energy ion beam by performing reciprocal scanning and collimation at a position downstream of the beam acceleration unit 120, highly accurate energy analysis, control of energy dispersion, orbit correction, adjustment of beam convergence and divergence, and the like may be performed in advance.

The beam deflection unit 130 performs energy analysis, energy dispersion control, and orbit correction of the high-energy ion beam output from the beam acceleration unit 120. The beam deflection unit 130 forms a portion extending in an arc shape of the beamline BL. The high-energy ion beam is redirected by the beam deflection unit 130 toward the beam transport unit 140.

The beam deflection unit 130 includes an energy analysis electromagnet 132, a lateral focusing quadrupole lens 134 that suppresses energy dispersion, an energy analysis slit 136, a first Faraday cup 138a, a deflection electromagnet 139 that provides steering (orbit correction), and a second Faraday cup 138b. The energy analysis electromagnet 132 is also referred to as an energy-filtering electromagnet (EFM). In addition, a device group including the energy analysis electromagnet 132, the lateral focusing quadrupole lens 134, the energy analysis slit 136, and the first Faraday cup 138a is also collectively referred to as an “energy analysis device”.

The energy analysis slit 136 may be configured such that a slit width is variable in order to adjust a resolution of energy analysis. The energy analysis slit 136 includes, for example, two shielding bodies movable in a slit width direction, and may be configured such that the slit width can be adjusted by changing an interval between the two shielding bodies. The energy analysis slit 136 may be configured such that the slit width is variable by selecting any one of a plurality of slits having different slit widths.

The first Faraday cup 138a is disposed immediately after the energy analysis slit 136 and is used for beam current measurement for energy analysis. The second Faraday cup 138b is disposed immediately after a deflection electromagnet 139 and is provided for beam current measurement of the ion beam subjected to orbit correction and entering the beam transport unit 140. The first Faraday cup 138a and the second Faraday cup 138b are configured to be taken in and out of the beamline BL by an operation of a Faraday cup drive unit (not illustrated).

The beam transport unit 140 forms another linearly extending portion of the beamline BL, and is provided so as to be parallel to the beam acceleration unit 120 with a maintenance area MA at the center of the device interposed therebetween. A length (a length in a Y direction) of the beam transport unit 140 may be designed to be about the same as a length of the beam acceleration unit 120. With the above configuration, a U-shaped layout is formed as a whole by the beamline BL including the beam acceleration unit 120, the beam deflection unit 130, and the beam transport unit 140.

The beam transport unit 140 includes a beam shaper 142, a beam scanner 144, a beam dump 145, a beam collimator 147, a final energy filter 148, and left and right Faraday cups 149L and 149R.

The beam shaper 142 includes a converging/diverging lens such as a quadrupole lens device (Q lens), and is configured to shape the ion beam having passed through the beam deflection unit 130 into a desired cross-sectional shape. The beam shaper 142 includes, for example, an electric-field-type three-stage quadrupole lens (also referred to as a triplet Q lens), and includes three electrostatic quadrupole lens devices. The beam shaper 142 can independently adjust the convergence or divergence of the ion beam in each of a horizontal direction (X direction) and the vertical direction (Z direction) by using three lens devices. The beam shaper 142 may include a magnetic-field-type lens device, or may include a lens device that shapes a beam by using both an electric field and a magnetic field.

The beam scanner 144 is a beam deflection device that is configured to provide reciprocal scanning with the beam and performs scanning with the shaped ion beam in the X direction. The beam scanner 144 includes a pair of scanning electrodes facing each other in a beam scanning direction (X direction). The pair of scanning electrodes is connected to a variable voltage power supply (not illustrated), and a voltage applied between the pair of scanning electrodes is periodically changed to change an electric field generated between the electrodes to deflect the ion beam at various angles. As a result, the scanning with the ion beam is performed over a scanning range indicated by the arrow X. The beam scanner 144 may be replaced with another beam scanning device, and the beam scanning device may be implemented as a magnet device using a magnetic field.

The beam scanner 144 causes the ion beam to be incident on the beam dump 145 provided at a position away from the beamline BL by deflecting the beam beyond the scanning range indicated by the arrow X. The beam scanner 144 temporarily diverts the ion beam from the beamline BL toward the beam dump 145, thereby blocking the ion beam, so that the ion beam does not reach the substrate transfer and processing unit 150 positioned downstream.

The beam collimator 147 is configured to make a traveling direction of the ion beam with which scanning is performed parallel to an orbit of the designed beamline BL. The beam collimator 147 includes a plurality of arc-shaped collimating lens electrodes in which a passage slit for the ion beam is provided at a central portion. The collimating lens electrode is connected to a high-voltage power supply (not illustrated), and causes an electric field generated by voltage application to act on the ion beam to align the traveling direction of the ion beam in parallel to the orbit of the beamline. Note that the beam collimator 147 may be replaced with another beam collimating device, and the beam collimating device may be implemented as a magnet device using a magnetic field.

The final energy filter 148 is configured to analyze the energy of the ion beam and deflect the ions of necessary energy downward (−Z direction) to guide the ions to the substrate transfer and processing unit 150. The final energy filter 148 may be referred to as an angular energy filter (AEF) and includes a pair of AEF electrodes for electric field deflection. The pair of AEF electrodes is connected to a high-voltage power supply (not illustrated). By applying a positive voltage to the upper AEF electrode and applying a negative voltage to the lower AEF electrode, the ion beam is deflected downward. Note that the final energy filter 148 may be implemented by a magnet device for magnetic field deflection, or may be implemented by a combination of a pair of AEF electrodes for electric field deflection and a magnet device for magnetic field deflection.

The left and right Faraday cups 149L and 149R are provided downstream of the final energy filter 148, and are disposed at positions where beams at a left end and a right end of the scanning range indicated by the arrow X can be incident. The left and right Faraday cups 149L and 149R are provided at positions where the left and right Faraday cups 149L and 149R do not block the beam directed to a wafer W, and measure the beam current during ion implantation into the wafer W.

The substrate transfer and processing unit 150 is provided downstream of the beam transport unit 140, that is, at the most downstream end of the beamline BL. The substrate transfer and processing unit 150 includes an implantation processing chamber 151, a beam monitor 152, a beam profiler 153, a profiler driving device 154, a substrate transfer device 155, and a load port 156. The implantation processing chamber 151 may be provided with a platen driving device (not illustrated) that holds the wafer W at the time of ion implantation and moves the wafer W in a direction (Z direction) orthogonal to the beam scanning direction (X direction).

The beam monitor 152 is provided at the most downstream end of the beamline BL inside the implantation processing chamber 151. The beam monitor 152 is provided at a position where the ion beam can be incident in a case where the wafer W is not present on the beamline BL, and is configured to measure a beam characteristic before the ion implantation process or between the ion implantation processes. The beam monitor 152 measures a beam current, a degree of beam parallelism, and the like as the beam characteristics. For example, the beam monitor 152 may be positioned near a transfer port (not illustrated) connecting the implantation processing chamber 151 and the substrate transfer device 155, and may be provided at a position vertically below the transfer port.

The substrate transfer and processing unit 150 may further be provided with the beam profiler 153 and the profiler driving device 154 in the implantation processing chamber 151. The beam profiler 153 is configured to measure the beam current at a position on a surface of the wafer W. The beam profiler 153 is configured to be movable in the X direction by an operation of the profiler driving device 154, is retracted from an implantation position where the wafer W is positioned during ion implantation, and is inserted into the implantation position when the wafer W is not at the implantation position. The beam profiler 153 can measure the beam current over the entire beam scanning range in the X direction by measuring the beam current while moving in the X direction. The beam profiler 153 may include a plurality of Faraday cups arranged in an array in the X direction so that beam currents at a plurality of positions in the beam scanning direction (X direction) can be simultaneously measured.

The beam profiler 153 may include a single Faraday cup for measuring the beam current or may include an angle measuring instrument for measuring beam angle information. The angle measuring instrument may include, for example, a slit and a plurality of current detection units provided away from the slit in the beam traveling direction (Y direction). For example, the angle measuring instrument can measure an angle component of the beam in a slit width direction by measuring the beam having passed through the slit by the plurality of current detection units arranged in the slit width direction. The beam profiler 153 may include a first angle measuring instrument capable of measuring angle information in the X direction and a second angle measuring instrument capable of measuring angle information in the Z direction.

The substrate transfer device 155 is configured to transfer the wafer W between the load port 156 on which a wafer container 157 is placed and the implantation processing chamber 151. The load port 156 is configured such that a plurality of wafer containers 157 can be placed simultaneously, and includes, for example, four placing tables arranged in the X direction. A wafer container transfer port (not illustrated) may be provided vertically above the load port 156 so that the wafer container 157 can pass in the vertical direction. The wafer container 157 may be automatically carried into the load port 156 through the wafer container transfer port by a transfer robot installed on a ceiling or the like in a semiconductor manufacturing factory where the ion implanter 100 is installed, and may be automatically carried out from the load port 156, for example.

The ion implanter 100 further includes a central control device 160. The central control device 160 controls the overall operation of the ion implanter 100. The central control device 160 is implemented by an element including a central processing unit (CPU) and a memory of a computer or a mechanical device as hardware, and is implemented by a computer program or the like as software. Various functions provided by the central control device 160 can be implemented by cooperation of hardware and software.

In the vicinity of the central control device 160, an operation panel 162 including a display device and an input device for setting an operation parameter of the ion implanter 100 is provided. Positions of the operation panel 162 and the central control device 160 are not particularly limited, but for example, the operation panel 162 and the central control device 160 can be disposed adjacent to an entrance 164 of the maintenance area MA between the beam generation unit 110 and the substrate transfer processing unit 150. By making positions of the ion source 112, the load port 156, the operation panel 162, and the central control device 160, which are frequently operated by an operator who manages the ion implanter 100, adjacent to each other, for example, operation efficiency can be increased.

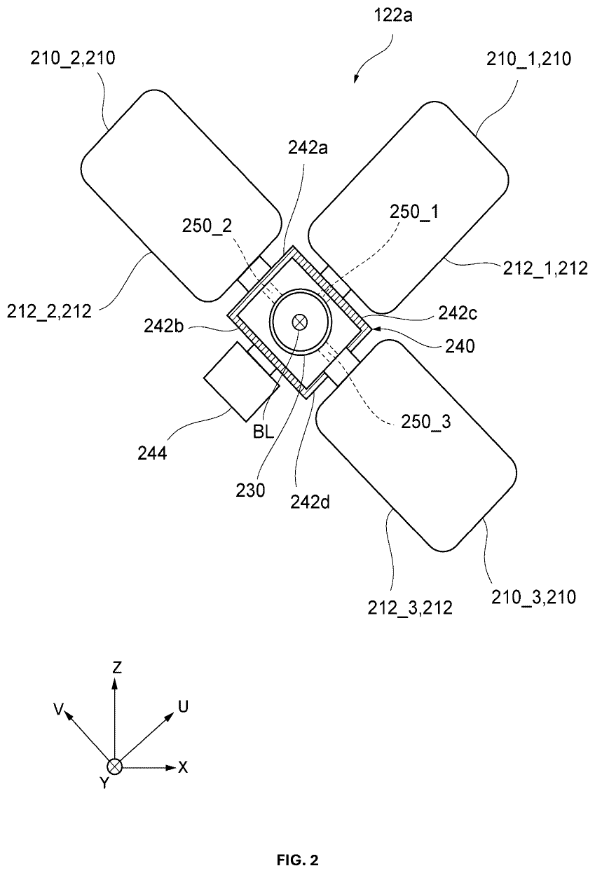

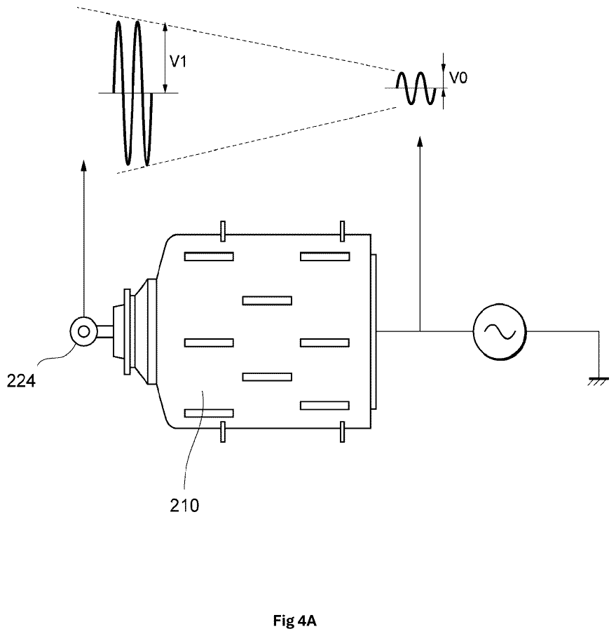

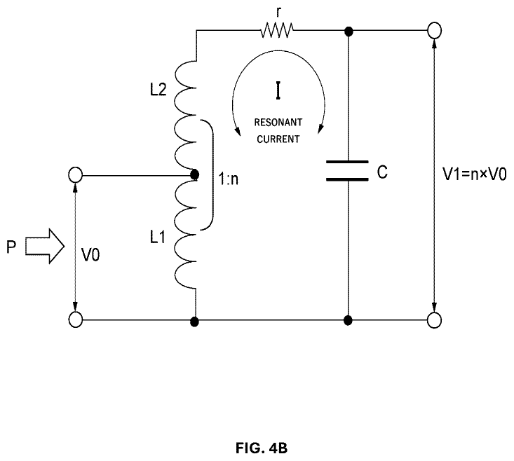

An arrangement of resonators 210 in the embodiment of the present disclosure will be described with reference to FIG. 2. In FIG. 2, for the sake of simplicity, only a resonator 210_1, a resonator 210_2, and a resonator 210_3 among the resonators 210 provided in the linear acceleration device 122a are illustrated. As illustrated in FIG. 2, the first linear acceleration device 122a includes a vacuum chamber 240 in which a resonator electrode (a resonator electrode 224 illustrated in FIG. 4A and the like described below) of the resonator 210 is disposed. The vacuum chamber 240 extends in the Y direction along the beamline BL, has a rectangular shape when viewed in a cross section (XZ cross section) of the vacuum chamber 240 in a direction orthogonal to the traveling direction (+Y direction) of the beamline, and has four partition walls extending in the Y direction. In the present embodiment, the vacuum chamber 240 has an upper wall 242a, a left wall 242b, a right wall 242c, and a lower wall 242d as the four partition walls.

As illustrated in FIG. 2, the vacuum chamber 240 is disposed so as to be oriented in a direction rotated by 45 degrees about the Y axis from the vertical direction (Z direction). The upper wall 242a is not disposed on a vertically upper side (+Z direction) when viewed from the beamline BL, but is disposed on an upper left side (+V direction). The +V direction corresponds to a direction of a vector obtained by combining unit vectors in the −X direction and the +Z direction. The left wall 242b is disposed on a lower left side (−U direction) when viewed from the beamline BL. The −U direction corresponds to a direction of a vector obtained by combining unit vectors in the −X direction and the −Z direction. The right wall 242c is disposed on an upper right side (+U direction) when viewed from the beamline BL. The +U direction corresponds to a direction of a vector obtained by combining unit vectors in the +X direction and the +Z direction. The lower wall 242d is disposed on a lower right side (−V direction) when viewed from the beamline BL. The −V direction corresponds to a direction of a vector obtained by combining unit vectors in the +X direction and the −Z direction.

As illustrated in FIG. 2, the first resonator (first radio-frequency resonator) 210_1 is provided on an outer side of the right wall 242c and is disposed at a position in the +U direction when viewed from the beamline BL. The first resonator 210_1 is connected to the resonator electrode in the vacuum chamber 240 via a first stem 250_1 extending in the +U direction when viewed from the beamline BL.

The second resonator (second radio-frequency resonator) 210_2 is provided on an outer side of the upper wall 242a and is disposed at a position in the +V direction when viewed from the beamline BL. The second resonator 210_2 is connected to the resonator electrode in the vacuum chamber 240 via a second stem 250_2 extending in the +V direction when viewed from the beamline BL.

The third resonator (third radio-frequency resonator) 210_3 is provided on an outer side of the lower wall 242d and is disposed at a position in the-V direction when viewed from the beamline BL. The third resonator 210_3 is connected to the resonator electrode in the vacuum chamber 240 via a third stem 250_3 extending in the −V direction when viewed from the beamline BL.

In the present embodiment, no resonator 210 is provided on an outer side of the left wall 242b. A vacuum evacuation device 244 for evacuating the inside of the vacuum chamber 240 may be provided on the left wall 242b. The vacuum evacuation device 244 may be disposed at a position in the −U direction when viewed from the beamline BL.

As illustrated in FIG. 2, by disposing the vacuum chamber 240 rotated by 45 degrees from the horizontal direction (X direction) or the vertical direction (Z direction), ranges occupied by the resonators 210_1 to 210_3 in the X direction and the Y direction can be reduced, so that the entire first linear acceleration device 122a can be downsized.

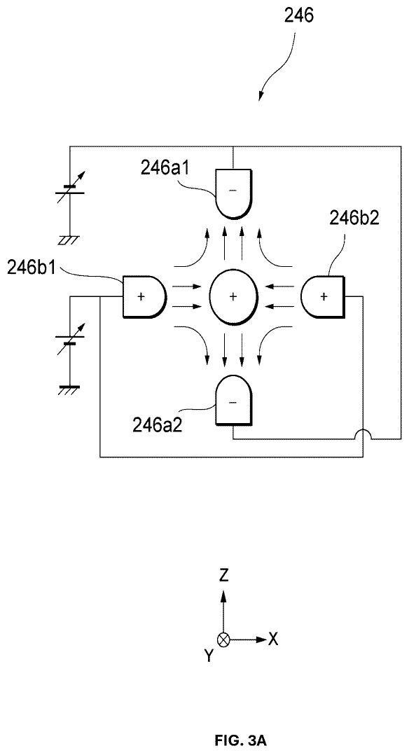

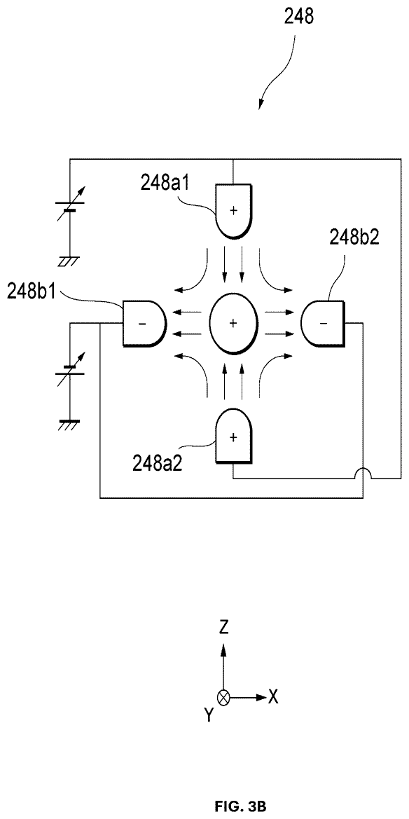

An operation model of convergence of the ion beam by an electrostatic quadrupole lens 246 and an electrostatic quadrupole lens 248 will be described with reference to FIGS. 3A and 3B. FIG. 3A is a schematic view (cross-sectional view) of the lateral focusing lens 246 when viewed from an upstream side (−Y direction) in the traveling direction of the ion beam. FIG. 3B is a schematic view (cross-sectional view) of the longitudinal focusing lens 248 when viewed from the upstream side (−Y direction) in the traveling direction of the ion beam.

As illustrated in FIG. 3A, in the lateral focusing electrostatic quadrupole lens 246, a negative potential is applied vertically (+Z direction and −Z direction), and a positive potential is applied laterally (+X direction and −X direction). As a result, in the lateral focusing electrostatic quadrupole lens 246, an attractive force is generated between an electrode 246a1 and an electrode 246a2 having a negative potential and a repulsive force is generated between an electrode 246b1 and an electrode 246b2 having a positive potential for the ion beam including ion particles having a positive charge, so that the ion beam is converged in a lateral direction (X direction) and diverged in a longitudinal direction (Z direction), and a shape of the ion beam can be adjusted.

As illustrated in FIG. 3B, in the longitudinal focusing electrostatic quadrupole lens 248, a positive potential is applied vertically (+Z direction and −Z direction), and a negative potential is applied horizontally (+X direction and −X direction). As a result, in the longitudinal focusing electrostatic quadrupole lens 248, a repulsive force is generated between an electrode 248a1 and an electrode 248a2 having a positive potential and an attractive force is generated between an electrode 248b1 and an electrode 248b2 having a negative potential for the ion beam including the ion particles having a positive charge, so that the ion beam can be converged in the longitudinal direction (Z direction) and diverged in the lateral direction (X direction), and the shape of the ion beam can be adjusted.

FIG. 4A schematically illustrates a power system of the resonator 210. FIG. 4B illustrates an equivalent circuit thereof. As illustrated in FIG. 4A, for example, an RF amplifier is connected to the resonator 210, and power P is supplied from the RF amplifier. A ratio of a voltage V1 at an output terminal to a voltage V0 at an input terminal is a winding number ratio n of an input coupling coil in the equivalent circuit illustrated in FIG. 4B.

As described above, in the ion implanter 100 according to the embodiment of the present disclosure, at least some of the plurality of resonators 210 are configured such that a gas for cooling at least the coil is present in a housing 212, and a configuration for generating a flow of the gas for promoting the cooling of at least the coil is provided in the vicinity of the coil, whereby the inside of the resonator 210 can be effectively cooled. Such configurations, actions, and effects in the embodiment of the present disclosure may be applied to, for example, the first (upstream) several (e.g., two) resonators 210 among the resonators 210 that can be used for generating the bunched beam. Hereinafter, a case where the configuration according to the embodiment of the present disclosure is applied to two resonators 210 positioned upstream in the beam traveling direction will be described as an example.

FIG. 5A is a side view of the resonator 210 when viewed from an upstream side (−Y direction) in the traveling direction of the ion beam, FIG. 5B is a side view of the resonator 210 when viewed from a direction (U direction) perpendicular to the beam traveling direction, and FIG. 5C is a cross-sectional view (a cross-sectional view perpendicular to a U axis) of the resonator 210. In FIGS. 5A to 5C, for the sake of explanation, a longitudinal direction of the housing 212 of the resonator 210 is illustrated to be parallel to a longitudinal direction on the drawing, but in the embodiment of the present disclosure, as illustrated in FIG. 2, the resonator 210 may be disposed at a position inclined by 45°, for example, in the +X direction or the −X direction from the vertical direction.

As illustrated in FIGS. 5A, 5B, and 5C, the vacuum chamber 240 is disposed in the −V direction of the resonator 210, and ground electrodes 230_1 and 230_2 are provided in the vacuum chamber 240. The housing 212 of the resonator 210 is provided with a plurality of opening portions 262. The opening portion 262 is described below.

As illustrated in FIG. 5C, the resonator 210 includes a fan 214 and a resonator control circuit 216, which are provided at an upper portion (+V direction) of the resonator 210, a tuner 218 that is provided inside the resonator 210 and adjusts a resonant frequency, a coil 226, a stem head 228, and a cone member 234. As described above, the stem 250 is further provided inside the resonator 210 so as to extend to the vacuum chamber 240 through an attachment hole 236 below (−V direction) the stem head 228, and the stem 250 supports the resonator electrode 224 such that the resonator electrode 224 is disposed between the pair of ground electrodes 230. The resonator electrode 224 has, for example, a hollow portion, and is disposed such that a central axis direction of the hollow portion is parallel to the Y direction, thereby allowing the ion beam to pass through the hollow portion. That is, in the present embodiment, the pair of ground electrodes 230_1 and 230_2 and the resonator electrode 224 are arranged such that a central axis of the resonator electrode 224 is substantially aligned with the centers of beam entrance ports 230_1a and 230_2a of the ground electrodes 230_1 and 230_2. The resonator electrode 224 may be a rectangular parallelepiped tube in one embodiment, or may be a cylindrical tube in another embodiment.

The coil 226 has a spirally wound shape. The housing 212 of the resonator 210 may have a cylindrical shape surrounding the spiral coil 226. In addition, in the present embodiment, the coil 226 may be formed to be solid or hollow. A surface of the coil 226 may be plated with a good electrical conductor. The number of windings of the coil 226 is not limited to the number of windings illustrated in FIG. 5C, and may be appropriately changed.

The cone member 234 is provided outside the vacuum chamber 240 and inside the resonator 210. The cone member 234 is attached to the upper wall 242a of the vacuum chamber 240 and is configured to support the stem 250. The cone member 234 is formed in a conical shape and is provided so as to close the attachment hole 236. In the present embodiment, the vacuum chamber 240 is at a ground potential, and the cone member 234 is configured to be electrically insulated from the stem 250 to which a radio-frequency voltage V_{RF} is applied.

As described above, the ion implanter 100 according to the embodiment of the present disclosure is the ion implanter 100 including the linear acceleration unit (beam acceleration unit 120) that adjusts the energy of the ions, in which the beam acceleration unit 120 includes the plurality of resonators 210 (such as resonators 210_1, 210_2, . . . , and 210_n (n is any natural number)), and each of the plurality of resonators 210 is configured to accelerate or decelerate the ions by applying the radio-frequency electric field to the ions, and includes the electrode (resonator electrode 224) for generating the radio-frequency electric field, the coil (coil 226), the stem 250 that connects the resonator electrode 224 and the coil 226, and the housing 212 that surrounds the coil 226. Furthermore, in the ion implanter 100 according to the embodiment of the present disclosure, at least one of the plurality of resonators 210 is configured such that a gas for cooling at least the coil 226 is present inside the housing 212, and has a configuration for generating a flow of the gas for promoting the cooling of at least the coil 226 in the vicinity of the coil. In the ion implanter 100 according to the present embodiment, with the above configuration, it is possible to effectively cool the configuration such as the coil 226 in the resonator 210.

For example, in the resonator 210 illustrated in FIGS. 5A, 5B, and 5C, since the housing 212 is provided with the plurality of opening portions 262, it is possible to cause a gas (for example, air) outside the housing 212 to flow into the inside of the housing 212 and to generate a flow of the gas for promoting the cooling of the configuration in the housing 212, such as the coil 226 in the housing 212. In the resonator 210 illustrated in FIGS. 5A, 5B, and 5C, the fan 214 is provided, so that it is possible to further promote the flow of the gas in the housing 212. Therefore, in the resonator 210 illustrated in FIGS. 5A, 5B, and 5C, for example, the plurality of opening portions 262, the fan 214, and the like are configured to generate a flow of the gas for promoting the cooling of the configuration in the housing 212, such as the coil 226 according to the present embodiment.

In the ion implanter 100 according to the present embodiment, other configurations provided in the resonator 210 than the coil 226, for example, the stem 250, the stem head 228, and the tuner 218, may also be cooled.

In the present embodiment, the gas used for the cooling may contain at least one of hydrogen, helium, and air. For example, a mixed gas of hydrogen and helium may be used as the gas used for the cooling. When a mixed gas of hydrogen and helium is used, the housing 212 may have a sealing structure so that the mixed gas does not leak to the outside of the housing 212.

Hereinafter, a more detailed configuration will be described focusing on a configuration for generating a flow of the gas for promoting the cooling of at least the coil 226 in the resonator 210 in the ion implanter 100 according to the embodiment of the present disclosure.

The ion implanter 100 according to the present embodiment may have a configuration in which a gas flows in from the outside of the housing 212. At this time, the ion implanter 100 may be configured to generate a flow of the gas inside the housing 212 by causing the gas to flow into the inside of the housing 212 from the outside of the housing 212 and causing the gas to flow out to the outside of the housing 212 from the inside of the housing 212. In the present embodiment, the resonator 210 may be disposed in, for example, air, and the gas flowing into the inside of the housing 212 and flowing out to the outside of the housing 212 may be, for example, air.

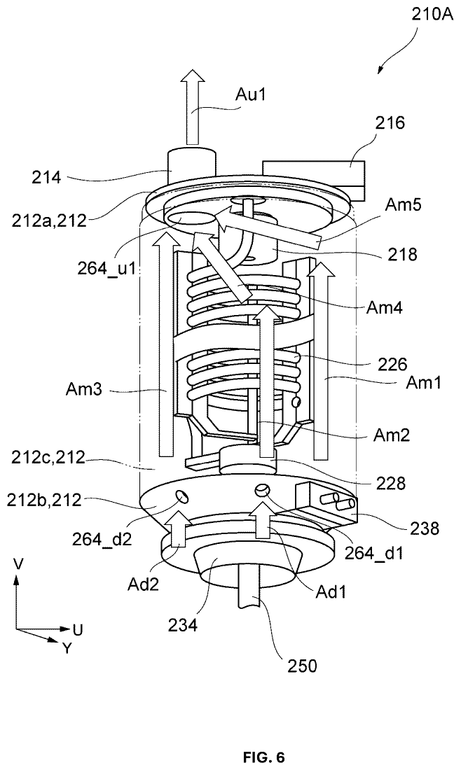

FIG. 6 is an internal transparent perspective view of an example of a configuration in which the gas flows in from the outside of the housing. The housing 212 of the resonator 210A illustrated in FIG. 6 may include, for example, a lid portion 212a, a bottom portion 212b, and a wall portion 212c coupling the lid portion 212a and the bottom portion 212b, and one or more opening portions (an opening portion 264_u1 of the lid portion 212a and an opening portion 264_d1 and an opening portion 264_d2 of the bottom portion 212b) may be provided in the lid portion 212a and the bottom portion 212b.

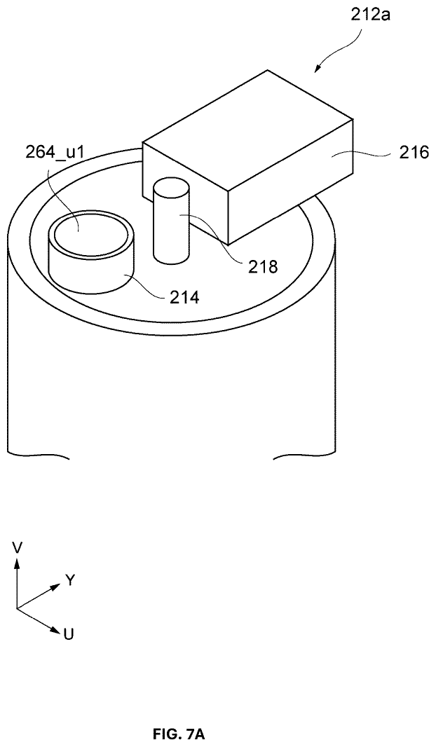

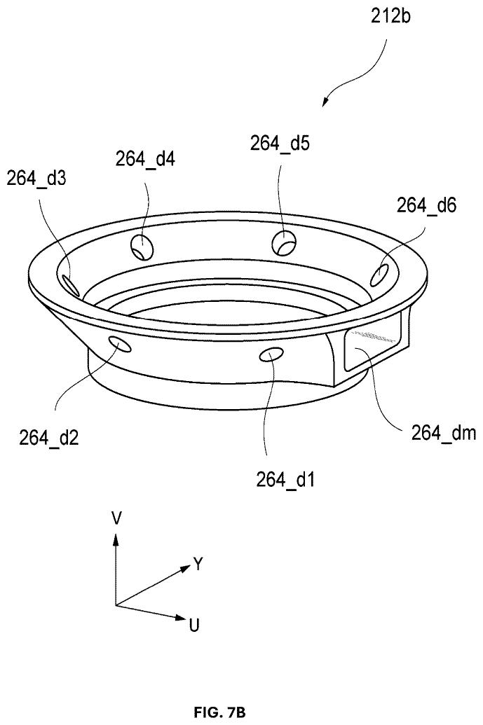

FIGS. 7A and 7B are perspective views of the vicinity of the lid portion 212a and the bottom portion 212b, respectively. As illustrated in FIG. 7A, the opening portion 264_u1 is provided in the lid portion 212a, and the fan 214 (not illustrated in FIG. 7A) is disposed in the opening portion 264_u1. As illustrated in FIG. 7B, circular opening portions 264_d1, 264_d2, 264_d3, 264_d4, 264_d5, and 264_d6 are provided in the bottom portion 212b. The bottom portion 212b is also provided with a rectangular opening portion 264_dm. A measuring instrument 238 (FIG. 6) may be disposed in the opening portion 264_dm.

A flow of the gas in the resonator 210A including the lid portion 212a and the bottom portion 212b having a configuration in which the opening portions are provided as described above is schematically indicated by arrows in FIG. 6. As illustrated in FIGS. 6, 7A, and 7B, in the resonator 210A, for example, the opening portions 264_d1, 264_d2, 264_d3, 264_d4, 264_d5, and 264_d6 at the bottom portion serve as suction ports for the gas (for example, air), the opening portion 264_u1 of the lid portion 212a serves as a discharge port for the gas, suction (arrows Ad1 and Ad2) and discharge (arrow Au1) of the gas into and from the resonator 210A occur, and a flow of the gas in the +V direction (arrows Am1, Am2, Am3, Am4, and Am5) is generated in the housing 212 of the resonator 210A. With such a configuration, in the resonator 210A, the gas can flow into the inside of the housing 212 from the outside of the housing 212, and the gas can flow out to the outside of the housing 212 from the inside of the housing 212 to generate a flow of the gas inside the housing 212.

As described above, in the resonator 210A illustrated in FIGS. 6, 7A, and 7B, the opening portion 264_u1 of the lid portion 212a serving as the discharge port for the gas and the opening portions 264_d1, 264_d2, 264_d3, 264_d4, 264_d5, and 264_d6 of the bottom portion 212b serving as the suction ports for the gas may be configured to generate a flow of the gas for promoting cooling of each component in the housing 212, such as the coil 226 according to the present embodiment. In addition, since a flow of the gas from the opening portions 264_d1, 264_d2, 264_d3, 264_d4, 264_d5, and 264_d6 of the bottom portion 212b to the opening portion 264_u1 of the lid portion 212a can be further promoted by the fan 214, the fan 214 may also be configured to generate a flow of the gas for promoting the cooling of the configuration in the housing 212, such as the coil 226.

In the example illustrated in FIG. 6, the discharge of the gas from the opening portion 264_u1 of the lid portion 212a is further promoted by providing the fan 214. However, even if the fan 214 is not provided, the flow of the gas can be generated by providing the opening portion 264_u1 in the lid portion 212a and the opening portions 264_d1, 264_d2, 264_d3, 264_d4, 264_d5, and 264_d6 in the bottom portion 212b.

For example, it is also possible to promote generation of an airflow by disposing one of the opening portions provided in the lid portion 212a and the bottom portion 212b respectively so as to be positioned vertically above and below the other one of the opening portions. That is, the configuration for generating a flow of the gas according to the present embodiment may include a plurality of openings (opening portions 264) provided in the housing 212, and the plurality of openings may include a first opening (for example, the opening portions 264_d1, 264_d2, 264_d3, 264_d4, 264_d5, and 264_d6) and a second opening (for example, the opening portion 264_u1) that is positioned vertically above the first opening in a use state. As a result, for example, the air outside the resonator 210A can generate an airflow flowing in from the first opening and flowing out from the second opening.

In FIGS. 6, 7A, and 7B, for the sake of explanation, a case where the longitudinal direction of the resonator 210A is a direction substantially parallel to the drawing is exemplified. However, even in a case where the resonator 210 is disposed in another direction, similarly, at least one of the plurality of openings is disposed relatively vertically above or below at least one of the openings other than the opening, whereby the airflow can be effectively generated in the housing 212. For example, even in a case where the resonator 210_1 illustrated in FIG. 2 is disposed to face the +U direction, at least one (first opening) of the plurality of openings may be disposed in the −U direction (a direction from the lid portion (corresponding to the lid portion 212a of the resonator 210A illustrated in FIG. 6) toward the bottom portion (corresponding to the bottom portion 212b of the resonator 210A illustrated in FIG. 6)) with respect to at least one (second opening) of the other openings. Similarly, the first opening of the resonator 210_2 may be disposed in the −V direction (a direction from the lid portion toward the bottom portion) with respect to the second opening, and similarly, the first opening of the resonator 210_3 may be disposed in the −V direction (a direction from the bottom portion toward the lid portion) with respect to the second opening.

As described above, even in a case where the resonator 210 is disposed so as to be inclined with respect to the vertical direction, the first opening and the second opening are disposed such that one of the first and second openings is positioned vertically (Z direction) above or below the other in the use state, whereby the airflow can be effectively generated.

In addition, as in the resonator 210A illustrated in FIGS. 6, 7A, and 7B, by providing the fan 214 in addition to the openings (the opening portion 264_u1 and the opening portions 264_d1, 264_d2, 264_d3, 264_d4, 264_d5, and 264_d6), the fan 214 serves as a convection generation mechanism in the housing 212, so that it is possible to more effectively cool the coil 226 and the like in the housing 212. At this time, the configuration for generating a flow of the gas in the present embodiment may include at least one of a first airflow generation mechanism that is provided in the first opening (for example, the opening portions 264_d1, 264_d2, 264_d3, 264_d4, 264_d5, and 264_d6) and promotes generation of a flow of the gas flowing into the inside of the housing 212 through the first opening portions 264_d1, 264_d2, 264_d3, 264_d4, 264_d5, and 264_d6 and flowing out to the outside of the housing 212 through the second opening (for example, the opening portion 264_u1), and a second airflow generation mechanism (for example, the fan 214) that is provided in the second opening portion 264_u1 and promotes generation of a flow of the gas flowing into the inside of the housing 212 through the first opening portions 264_d1, 264_d2, 264_d3, 264_d4, 264_d5, and 264_d6 and flowing out to the outside of the housing 212 through the second opening portion 264_u1.

Therefore, in the examples illustrated in FIGS. 6, 7a, and 7b, a case where the fan 214 serving as the airflow generation mechanism (second airflow generation mechanism) is provided in the opening portion 264_u1 is exemplified, but the airflow generation mechanism is not limited thereto, and another airflow generation mechanism may be provided in one or more of the opening portions 264_d1, 264_d2, 264_d3, 264_d4, 264_d5, and 264_d6. In FIGS. 6, 7A, and 7B, in a case where the airflow generation mechanisms are provided in the opening portions 264_d1, 264_d2, 264_d3, 264_d4, 264_d5, and 264_d6 provided in the −V direction with respect to the opening portion 264_u1, for example, a suction fan may be used. By providing suction fans in the opening portions 264_d1, 264_d2, 264_d 3, 26 4_d4, 264_d 5, and 2 6 4_d6 in addition to the discharge fan 214 provided in the opening portion 264_u1, the generation of the airflow can be further promoted.

In FIGS. 6, 7A, and 7B, a case where one opening portion 264_u1 is provided in the lid portion 212a and the fan 214 is provided in the opening portion 264_u1 is exemplified, but the opening portions are not limited thereto, and a plurality of opening portions may be provided, and each fan may be provided in at least one of the plurality of opening portions.

In addition, FIG. 7B illustrates a case where six opening portions 264_d1, 264_d2, 264_d3, 264_d4, 264_d5, and 264_d6 are provided in the bottom portion 212b, but the number of opening portions is not limited thereto, and five or less openings or seven or more openings may be provided. Further, the plurality of opening portions may be provided at equal intervals or do not have to be provided at equal intervals. In the present embodiment, the opening portions 264_d1, 264_d2, 264_d3, 264_d4, 264_d5, and 264_d6 of the bottom portion 212b may each have a diameter of 16 mm, for example. In a case where the number of openings or the size of the opening is changed, the opening portions may be designed such that the total area of all the openings is constant while increasing the number of openings, for example, by setting the diameter of the opening portion to 13.86 mm and setting the number of openings to eight.

As for the position where the opening is provided, as illustrated in FIGS. 6, 7A, and 7B, the openings may be provided in the lid portion 212a and the bottom portion 212b of the housing 212, and the opening positioned vertically above (the opening in the +V direction) may be provided in the wall portion 212c instead of the lid portion 212a. That is, the openings may be provided in the bottom portion 212b and the wall portion 212c. In addition, the opening positioned vertically above (the opening in the +V direction) may be provided in the lid portion 212a, and the opening positioned vertically below (the opening in the −V direction) may be provided in the wall portion 212c. Even in a case where the openings are provided in any of the above positional relationships, it is possible to effectively generate the airflow in the housing 212 by providing the plurality of openings so as to be positioned vertically above and below one another.

In the present embodiment, a temperature of the gas flowing into the inside of the housing 212 through the plurality of openings may be different from a temperature of the gas flowing out of the housing 212. For example, among the plurality of openings, the gas flowing out to the outside of the housing 212 from the second opening (for example, the opening portion 264_u1 illustrated in FIGS. 6 and 7A) positioned relatively vertically above may have a higher temperature than that of the gas flowing into the inside of the housing 212 from the first opening (for example, the opening portions 264_d1, 264_d2, 264_d3, 264_d4, 264_d5, and 264_d6 illustrated in FIGS. 6 and 7B) positioned relatively vertically below. As a result, heat in the housing 212 may be caused to flow out to the outside of the housing 212 by the gas flowing into the housing 212.

Further, in the configuration described above, a case where the plurality of openings are disposed so as to be positioned vertically above and below one another has been described as an example, but the arrangement of the openings is not limited thereto. For example, a cooling effect can be improved by generating convection in the housing 212 by the airflow generation mechanism such as the fan regardless of the positional relationship of the plurality of openings in the vertical direction.

That is, in the present embodiment, for example, the configuration for generating a flow of the gas may include a plurality of openings provided in the housing 212 and at least one fan, the plurality of openings may include a third opening and a fourth opening, and the at least one fan may include at least one of a third fan that is provided in the third opening and promotes generation of a flow of the gas flowing into the inside of the housing 212 through the third opening and flowing out to the outside of the housing 212 through the fourth opening, and a fourth fan that is provided in the fourth opening and promotes generation of a flow of the gas flowing into the inside of the housing 212 through the third opening and flowing out to the outside of the housing 212 through the fourth opening.

In addition, by providing both the third fan and the fourth fan, it is possible to more effectively generate the airflow from at least one of the plurality of openings (the third opening in the present embodiment) to at least one of the other openings (the fourth opening in the present embodiment). For example, by using a suction fan as the third fan and a discharge fan as the fourth fan, a flow of the gas for promoting the cooling of the configuration in the housing 212, such as the coil 226, may be generated in the housing 212. Even in a case where only one of the fans is provided, the airflow can be generated inside the housing 212. It is possible to effectively generate the airflow in the housing 212 regardless of whether one fan is provided or a plurality of fans are provided even in a case where the plurality of openings are not positioned vertically above and below one another.

As described above, even in a case where the plurality of openings are not positioned vertically above and below one another, at least one fan may be provided in the opening portion or the like to generate a flow of the gas for promoting the cooling of the configuration in the housing 212, such as the coil 226.

In FIGS. 6, 7A, and 7B, a case where the circular opening portions 264_d1, 264_d2, 264_d3, 264_d4, 264_d5, and 264_d6 are provided in the bottom portion 212b has been described as an example, but the shape of the opening portion is not limited thereto. The opening portions may have a shape other than a circular shape, for example, an elliptical shape or a polygonal shape such as a rectangular shape.

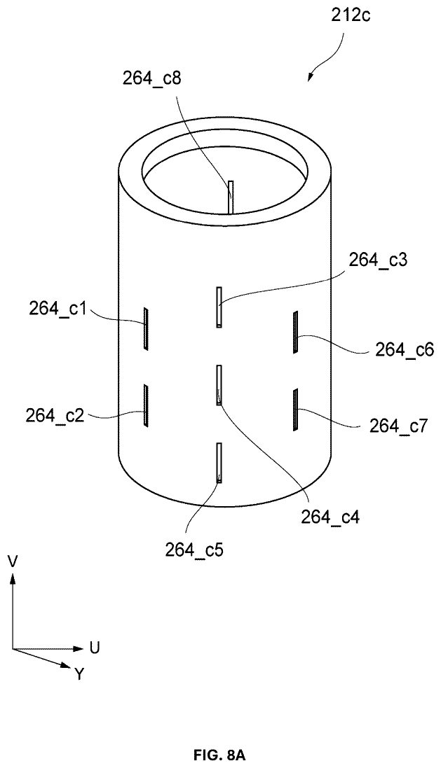

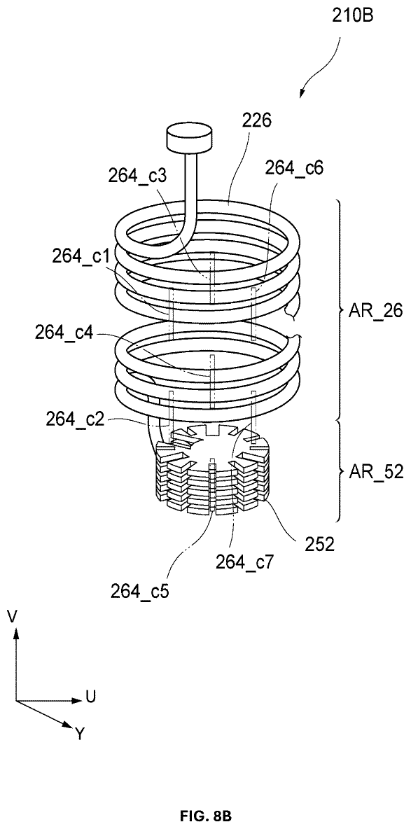

Further, in the ion implanter 100 of the present embodiment, the opening may be provided only in the wall portion 212c of the housing 212 of the resonator 210. FIG. 8A illustrates an example of the housing 212 in a case where a plurality of openings are provided in the wall portion 212c.

As illustrated in FIG. 8A, the wall portion 212c is provided with opening portions 264_c1, 264_c2, 264_c3, 264_c4, 264_c5, 264_c6, 264_c7, and 264_c8. For example, since the opening portions 264_c1, 264_c3, and 264_c6 are disposed relatively above the opening portions 264_c2, 264_c5, and 264_c7 in a V direction, similarly to the resonator 210A described with reference to FIGS. 6, 7A, and 7B, an airflow can be effectively generated in the housing 212. As described above, in the example illustrated in FIG. 8A, the plurality of opening portions 264_c1, 264_c2, 264_c3, 264_c4, 264_c5, 264_c6, 264_c7, and 264_c8 provided in the wall portion 212c may be configured to generate a flow of the gas for promoting the cooling of the configuration in the housing 212, such as the coil 226.

In addition, in a case where a plurality of openings are provided in the wall portion 212c, the openings may be provided in a staggered arrangement as illustrated in FIG. 8A. That is, in the present embodiment, the housing 212 may have a cylindrical shape, the plurality of openings may be arranged in an axial direction (V direction) and a circumferential direction (a circumferential direction in the cylindrical shape) of the cylindrical shape, and the openings adjacent in the circumferential direction (for example, the opening portion 264_c1 and the opening portion 264_c4 and/or 264_c3, and the opening portion 264_c2 and the opening portion 264 _c4 and/or 264_c5) may be arranged so to be offset from each other in the axial direction. In the present embodiment, for example, the openings adjacent to each other in the circumferential direction may be arranged so as to be offset from each other by 50 mm in the axial direction. As described below, by arranging the adjacent openings so as to be offset from each other by 50 mm, it is possible to effectively cool the inside of the housing 212 while suppressing leakage of an electromagnetic wave that may be generated due to the coil 226 to the outside of the housing 212.

In another embodiment, the openings adjacent to each other in the axial direction may be provided so as to be offset from each other in the circumferential direction. Also in this case, for example, the openings adjacent to each other in the axial direction may be arranged so as to be offset from each other by 50 mm in the circumferential direction.

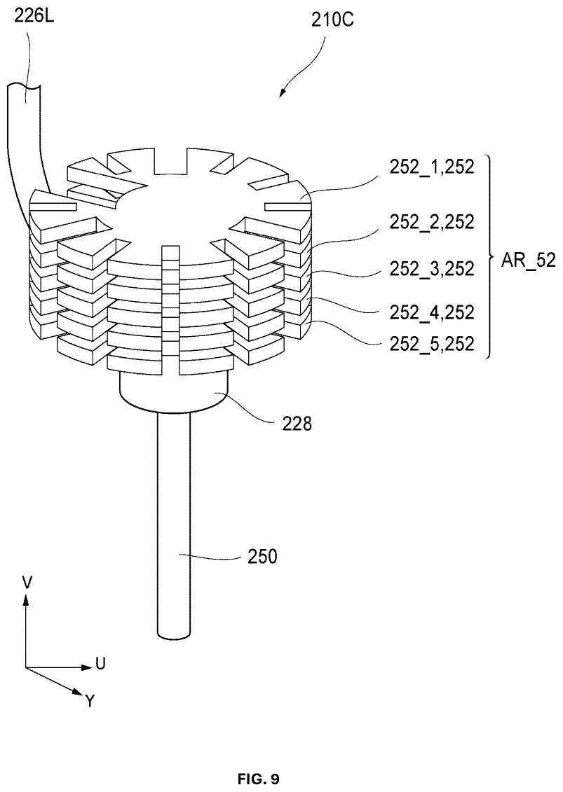

In a case where the plurality of openings are provided in a staggered arrangement as illustrated in FIG. 8A, the openings may be provided at positions where the respective configurations in the housing 212 can be effectively cooled. FIG. 8B schematically illustrates a positional relationship between a coil 226 and a fin-shaped heat sink 252 (described below) in a housing 212 of a resonator 210B and opening portions 264_c1, 264_c2, 264_c3, 264_c4, 264_c5, 264_c6, and 264_c7 provided in a staggered arrangement in a wall portion 212c, for example, in a case where the fin-shaped heat sink 252 is provided below the coil 226 (in the −V direction). In the housing 212, for example, in a region where the coil 226 is provided (coil region AR_26 in FIG. 8B), a temperature may rise due to input of heat mainly from a radio-frequency power supply or the like as a heat source. In addition, for example, in a region where the heat sink 252 is provided (heat sink region AR_52 in FIG. 8B), a temperature may increase due to input of heat generated when an ion beam mainly hits a resonator electrode (not illustrated in FIG. 8B) positioned below. In the present embodiment, by providing the opening portions 264_c1, 264_c2, 264_c3, 264_c4, 264_c5, 264_c6, and 264_c7 in the coil region AR_26 and the heat sink region AR_52 as illustrated in FIG. 8B, it is possible to effectively cool a region that is likely to have a relatively high temperature in the housing 212. The heat sink 252 is a heat dissipation portion in the present embodiment, and is described below with reference to FIG. 9 and the like.

As illustrated in FIG. 8A, the plurality of opening portions 264_c1, 264_c2, 264_c3, 264_c4, 264_c5, 264_c6, 264_c7, and 264_c8 provided in the wall portion 212c may each have, for example, an elongated shape. At this time, the shapes of the opening portions 264_c1, 264_c2, 264_c3, 264_c4, 264_c5, 264_c6, 264_c7, and 264_c8 may be, for example, elongated shapes extending in parallel to the axial direction (for example, the V direction) of the cylindrical shape of the housing 212 as illustrated in FIG. 8A.

Further, in a case where the plurality of opening portions 264_c1, 264_c2, 264_c3, 264_c4, 264_c5, 264_c6, 264_c7, and 264_c8 each have an elongated shape, the electromagnetic wave may be blocked, so that emission of the electromagnetic wave from the coil 226 to the outside of the housing 212 is suppressed.

For example, in a case where the plurality of opening portions 264_c1, 264_c2, 264_c3, 264_c4, 264_c5, 264_c6, 264_c7, and 264_c8 each have a rectangular shape (that is, an oblong shape) having long sides and short sides, when a wavelength of the electromagnetic wave that can be emitted from the coil 226 is λ, an area of each of the plurality of opening portions 264_c1, 264_c2, 264_c3, 264_c4, 264_c5, 264_c6, 264_c7, and 264_c8 may be (λ/10,000)² or more and (λ/100)² or less, a length of the long side of the rectangular shape of the opening may be λ/10,000 or more and λ/100 or less, a length of the short side may be λ/10,000 or more and λ/100 or less, and a ratio of the length of the short side to the length of the long side may be 1/1,000 or more and ½ or less. The area of each of the plurality of elongated opening portions 264_c1, 264_c2, 264_c3, 264_c4, 264_c5, 264_c6, 264_c7, and 264_c8, the length of the long side, and the length of the short side are set to such values and relationships with respect to the wavelength λ of the electromagnetic wave that can be generated by the coil 226, whereby the electromagnetic wave that can leak to the outside of the housing 212 can be effectively suppressed. That is, with such a configuration, it is possible to effectively cool the coil region AR_26 and the heat sink region AR_52 described above while suppressing the leakage of the electromagnetic wave from the housing 212 to the outside.

In a case where the plurality of opening portions 264_c1, 264_c2, 264_c3, 264_c4, 264_c5, 264_c6, 264_c7, and 264_c8 each have a rectangular shape having long sides and short sides, an area of each of the plurality of openings may be 0.2 mm² or more and 40,000 mm² or less, a length of the long side may be 0.5 mm or more and 200 mm or less, and a length of the short side may be 0.5 mm or more and 200 mm or less. Even with such a configuration, it is possible to effectively cool the coil region AR_26 and the stem region AR_50 described above while suppressing the leakage of the electromagnetic wave from the housing 212 to the outside.

The area of each of the plurality of openings is more preferably 1 mm² or more and 10,000 mm² or less, and still more preferably 5 mm² or more and 2,000 mm² or less. The area of each of the plurality of openings is more preferably 10 mm² or more and 1,000 mm² or less.

Further, the length of the short side of the rectangular shape of the opening is preferably 1 mm or more and 100 mm or less, more preferably 2 mm or more and 50 mm or less, and still more preferably 5 mm or more and 20 mm or less. Further, the length of the long side of the rectangular shape of the opening is preferably 1 mm or more and 100 mm or less, more preferably 2 mm or more and 50 mm or less, and still more preferably 5 mm or more and 20 mm or less.

In addition, in a case where the opening has a rectangular shape, a ratio of the length of the short side to the length of the long side is preferably 1/500 or more and ⅕ or less, more preferably 1/200 or more and 1/10 or less, and still more preferably 1/100 or more and 1/20 or less.

By setting the plurality of openings to have the sizes and relationships of the above numerical range, it is possible to effectively shield the electromagnetic wave.

In the above description, a case where the plurality of openings each have a rectangular shape (oblong shape) having long sides and short sides has been described as an example, but the shape of each of the plurality of openings is not limited thereto. The plurality of openings may each have, for example, a circular shape or a square shape, and a plurality of circular or square openings may be arranged as described above. Further, a part of the housing 212 may be formed as a mesh instead of or in addition to the openings. In a case where a part of the housing 212 is formed as a mesh, it is also possible to generate the airflow and achieve a cooling effect in the housing 212 by the same action and effect as those of the opening described above.

In the ion implanter 100 according to the present embodiment, the heat dissipation portion may be provided. That is, in the present embodiment, the heat dissipation portion that promotes heat release to the gas by increasing a surface area exposed to the gas may be provided inside the housing 212.

FIG. 9 is a schematic enlarged view of the vicinity of a place where the heat dissipation portion is provided (the vicinity of a lower end portion (lower end 226L) of a coil 226 (−V direction) and the vicinity of a heat sink 252) in a housing 212. As illustrated in FIG. 9, the heat sink 252 including a plurality of fins (fins 252_1, 252_2, 252_3, 252_4, and 252_5) may be provided partially or entirely inside a resonator 210C in this case. In the resonator 210C, for example, the heat sink 252 may be disposed above (+V direction) a stem head 228 disposed above (+V direction) a stem 250. That is, the stem head 228 is attached to a connection portion of the stem 250 connected to the coil 226, and the heat dissipation portion in the present embodiment may include the heat sink 252 provided on the stem head 228.

As described above, the stem 250 may have a high temperature due to propagation of heat generated in the vacuum chamber 240. By providing the heat sink 252 including the fins 252_1, 252_2, 252_3, 252_4, and 252_5 above the stem head 228, a surface area of a heat sink region AR_52 in which the heat sinks are provided can be increased, so that it is possible to effectively cool the heat sink region AR_52 heated to a high temperature by the heat propagated from the vacuum chamber 240. According to the study of the present inventors, by providing the heat sink 252 including the fins 252_1, 252_2, 252_3, 252_4, and 252_5 illustrated in FIG. 9, a temperature of the stem 250 can be lowered by 30° C. or more as compared with a case where the heat sink 252 is not provided.

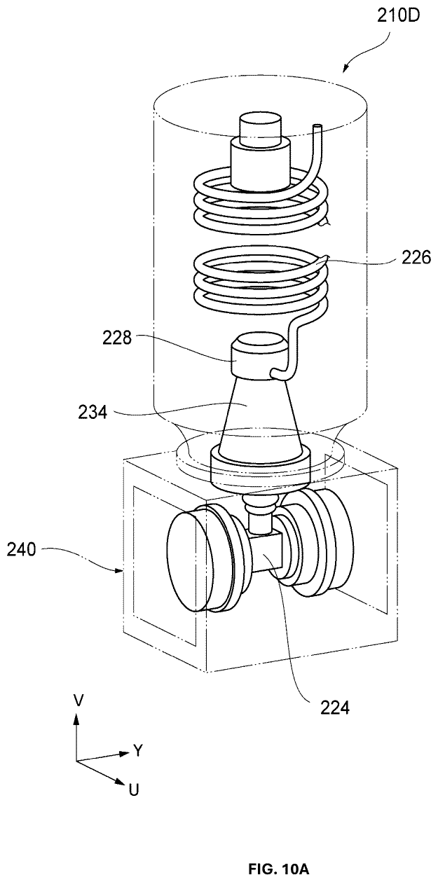

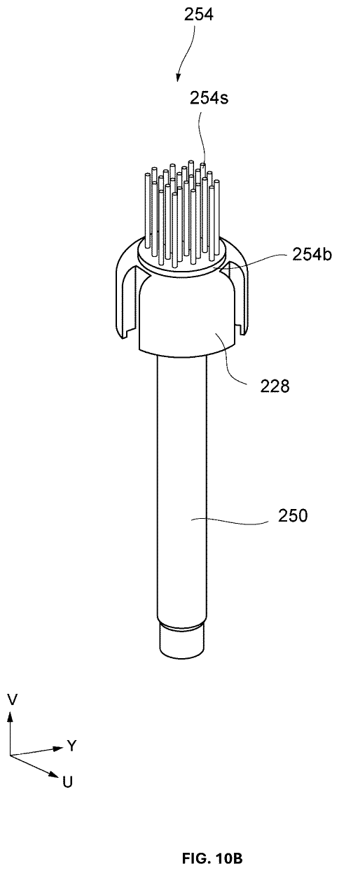

In the present embodiment, as the heat dissipation portion, a heat sink 254 may be provided above a stem head (head 228) provided above a stem 250 (+V direction). As illustrated in a perspective view (internal transparent perspective view) of the inside of a resonator 210D of FIG. 10A, for example, the stem 250 may be disposed inside a cone member 234 of the resonator 210D, the stem head 228 may be provided above (+V direction) the stem 250, and the heat sink 254 illustrated in FIG. 10B may be provided above (+V direction) the stem head 228. The heat sink 254 may include, for example, a base portion 254b and a plurality of rod-shaped fins 254s provided on the base portion 254b. By providing such a heat sink 254, a surface area in the vicinity of the stem head 228 can also be increased, so that cooling efficiency of the stem 250 and the stem head 228 can be improved. Therefore, by providing the heat sink 254, for example, it is possible to effectively cool each component inside the resonator 210D having a high temperature due to heat generated in the vacuum chamber 240 and propagated into a housing 212 through a resonator electrode 224 and the stem 250.

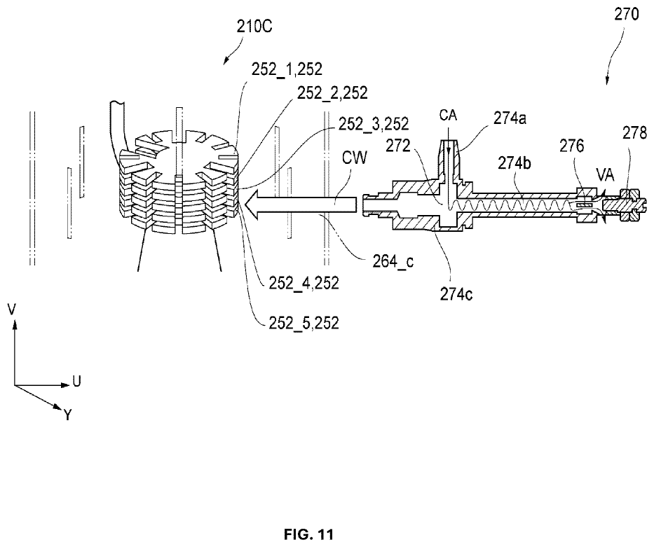

In a case where the heat dissipation portion (for example, the heat sink 252 including the fins 252_1, 252_2, 252_3, 252_4, and 252_5, or the heat sink 254) is provided, an air cooler configured to blow cold air for cooling the heat dissipation portion to the heat dissipation portion may be provided outside the housing 212. FIG. 11 illustrates a case where cold air CW is blown to the heat sink 252 by an air cooler 270 from the outside of the resonator 210C provided with the heat sink 252. In FIG. 11, the vicinity of the heat sink 252 including the fins 252_1, 252_2, 252_3, 252_4, and 252_5 in the resonator 210C is illustrated in an enlarged manner.

As illustrated in FIG. 11, the air cooler 270 includes, for example, a vortex generator 272, a first airflow path 274a, a second airflow path 274b, a third airflow path 274c, a flow straightening plate 276, and an adjustment screw 278. For example, when compressed air CA flows into the air cooler 270 from the first airflow path 274a, the introduced air is discharged by the vortex generator 272, expands and rotates at a high speed to become a vortex, and moves through the second airflow path 274b toward the flow straightening plate 276. In addition, an exhaust amount of exhausted air VA is adjusted by the flow straightening plate 276 and the adjustment screw 278. Unexhausted air becomes cold air and flows toward the resonator 210C through the third airflow path 274c while rotating in the same direction as an outer vortex in an inner cavity formed by a centrifugal force of the vortex, for example. In the housing 212, for example, a cold air port 264_c may be provided in the vicinity of the heat sink 252, and the cold air CW supplied from the air cooler 270 may be supplied into the housing 212 through the cold air port 264_c. With such a configuration, in the resonator 210C, the cooling effect in the vicinity of the fins 252_1, 252_2, 252_3, 252_4, and 252_5 can be further improved.

Similarly, in the resonator 210D (FIGS. 10A and 10B) provided with the heat sink 254, the cooling effect achieved by the heat sink 254 can be further improved by providing a cold air port 264_c in the vicinity of the heat sink 254.

In the ion implanter 100 according to the embodiment of the present disclosure, as described above, instead of a configuration in which the airflow is generated by the gas from the outside, for example, the inside of the housing 212 can be cooled by causing the gas in the housing 212 to internally circulate in the housing 212.

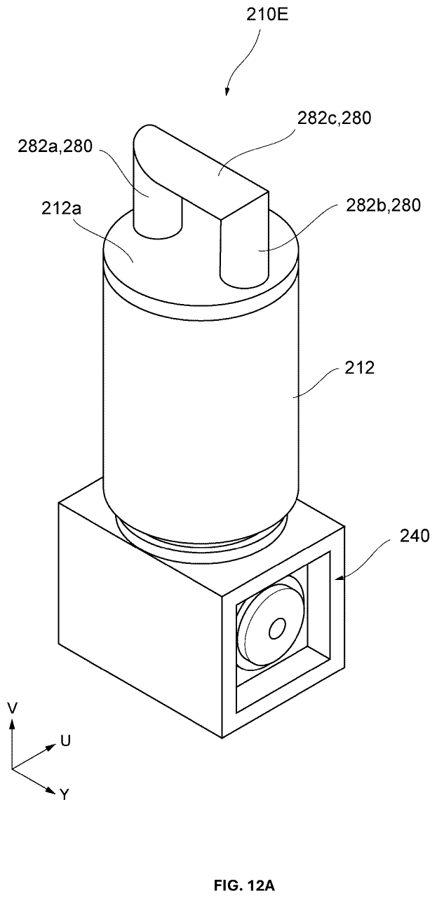

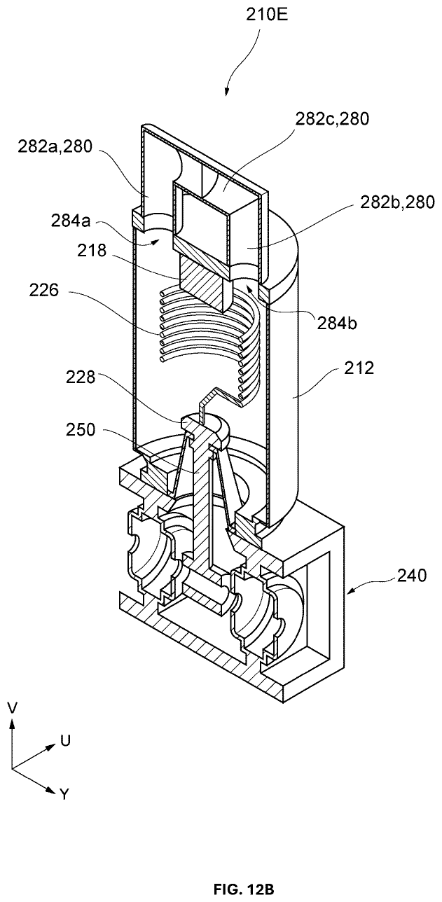

FIG. 12A is an external perspective view of a resonator 210E configured to generate convection of the gas in a housing 212 as a configuration for generating a flow of the gas for promoting cooling of the inside of the housing 212. FIG. 12B is a perspective view of a longitudinal section of the resonator 210E.

As illustrated in FIGS. 12A and 12B, a lid portion 212a of the housing 212 is provided with a pipe portion (circulation path 280) protruding in a direction away from the lid portion 212a (+V direction). The circulation path 280 includes a first straight portion 282a and a second straight portion 282b extending in the V direction, and a third straight portion 282c extending in the Y direction and connecting the first straight portion 282a and the second straight portion 282b. The circulation path 280 and the housing 212 are connected to the lid portion 212a through a first circulation port 284a (a first connection portion in the present embodiment) and a second circulation port 284b (a second connection portion in the present embodiment). In the resonator 210E, for example, an airflow generation mechanism such as an internal circulation fan may be provided in the circulation path 280, and a gas flowing into the circulation path 280 through the first circulation port 284a passes through the circulation path 280 and is discharged through the second circulation port 284b, or a gas flowing into the circulation path 280 through the second circulation port 284b passes through the circulation path 280 and is discharged through the first circulation port 284a, whereby the gas can be internally circulated in the housing 212. As a result, the inside of the housing 212 can be effectively cooled.

As in the resonator 210E illustrated in FIGS. 12A and 12B, in a case where the circulation path 280 and the internal circulation fan or the like are further provided, a flow of the gas for promoting the cooling of the configuration in the housing 212, such as a coil 226, may be generated by the internal circulation fan or the like in addition to the circulation path 280.

The circulation path 280 may have a diameter of 50 mm, for example. In a case where the inside of the housing 212 is cooled by internal circulation as in the resonator 210E, the housing 212 may be filled with, for example, helium as the gas. Further, the internal circulation fan may be configured to cause the gas to be internally circulated by being provided at another portion of the housing 212 either instead of being in the circulation path 280 or in addition to being in the circulation path 280.

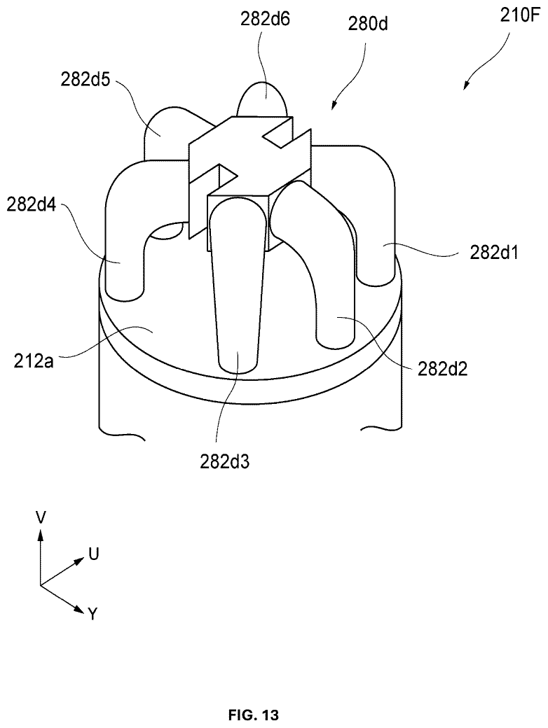

FIG. 13 is an enlarged view of the vicinity of a lid portion 212a of a resonator 210F including a circulation path 280d according to another example. In the present embodiment, the circulation path 280d (pipe portion) may include a plurality of pipe structures. As illustrated in FIG. 13, the circulation path 280d may be provided with, for example, a plurality of pipe structures 282d1, 282d2, 282d3, 282d4, 282d5, and 282d6. The pipe structures 282d1, 282d2, 282d3, 282d4, 282d5, and 282d6 may be arranged at equal intervals in a circumferential direction of the circular lid portion 212a, for example.

At this time, for example, one internal circulation fan may be provided above (+V direction) the vicinity of the center of the lid portion 212a where the pipe structures 282d1, 282d2, 282d3, 282d4, 282d5, and 282d6 intersect one another. Alternatively, a plurality of internal circulation fans (for example, six internal circulation fans) may be provided in the pipe structures 282d1, 282d2, 282d3, 282d4, 282d5, and 282d6, respectively. Alternatively, a plurality of internal circulation fans (for example, three internal circulation fans) may each be provided for a pair of pipe structures (for example, the pipe structures 282d1 and 282d4, the pipe structures 282d2 and 282d5, and the pipe structures 282d3 and 282d6) provided at positions axially symmetric with each other with respect to the center of the lid portion 212a (having a symmetry axis parallel to the V direction).

Further, the pipe structures 282d1, 282d2, 282d3, 282d4, 282d5, and 282d6 may be formed of, for example, metal or may be implemented by tubular members. As the pipe structures 282d1, 282d2, 282d3, 282d4, 282d5, and 282d6 are implemented by the tubular members, for example, it is possible to improve the degree of freedom of a position where the internal circulation fan is disposed and the degree of freedom of positions and shapes of the pipe structures 282d1, 282d2, 282d3, 282d4, 282d5, and 282d6, and thus, it is possible to save space in the ion implanter 100, for example.

In addition, as in the resonator 210F, by providing the circulation path 280d using the plurality of pipe structures 282d1, 282d2, 282d3, 282d4, 282d5, and 282d6, it is possible to improve cooling efficiency in the resonator 210F and to perform cooling more uniformly in the circumferential direction, for example, as compared with a case where one internal circulation path 280 (FIGS. 12A and 12B) is provided.

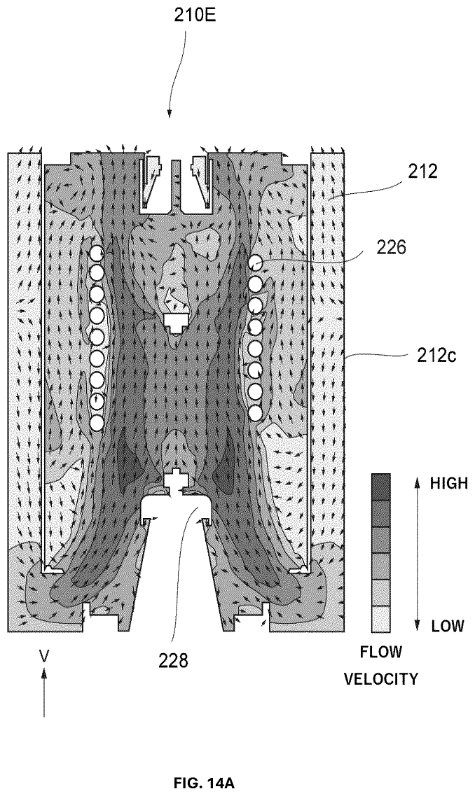

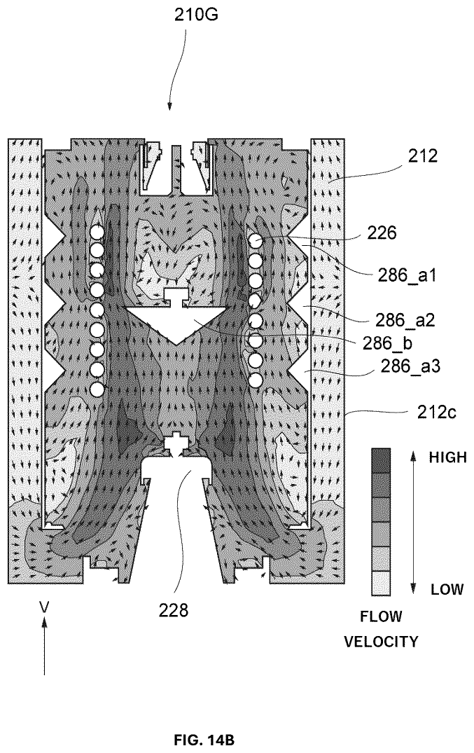

In the ion implanter 100 according to the present embodiment, a flow straightening plate that controls a direction of a flow of the gas may be provided inside the housing 212. Simulation results in the case of providing a flow straightening plate 286 in the configuration of the resonator 210E that cools the inside of the housing 212 by the internal circulation of the gas described above with reference to FIGS. 12A and 12B and the like will be described with reference to FIGS. 14A and 14B. FIG. 14A illustrates a simulation result of the airflow in the housing 212 of the resonator 210E in a case where the flow straightening plate 286 is not provided, and FIG. 14B illustrates a simulation result of an airflow in a housing 212 of a resonator 210G in a case where the flow straightening plate 286 is provided. In FIGS. 14A and 14B, a flow velocity vector of the airflow generated inside the housing 212 is indicated by an arrow, and a magnitude of the flow velocity is indicated by a contour.

As illustrated in FIG. 14B, the resonator 210G includes flow straightening plates 286_a1, 286_a2, and 286_a3 provided in a circumferential direction on an inner peripheral surface of a wall portion 212c of the housing 212, and a flow straightening plate 286_b provided in the vicinity of the center of the housing 212. Comparing FIGS. 14A and 14B, it can be seen that the flow velocity in the vicinity of the coil 226 (in particular, a region between the coil 226 and the flow straightening plate 286_b) is high. As a result, it can be seen that the flow velocity (a flow velocity in the +V direction) of the airflow in the vicinity of the coil 226 can be increased by providing the flow straightening plates 286_a1, 286_a2, 286_a3, and 286_b.

As illustrated in the simulation result of FIG. 14B, by providing the flow straightening plates 286_a1, 286_a2, 286_a3, and 286_b inside the housing 212, a flow of the gas for promoting the cooling of the configuration inside the housing 212, such as the coil 226, may be generated.

The flow straightening plates 286_a1, 286_a2, and 286_a3 provided on the inner peripheral surface of the wall portion 212c guide, for example, the gas particularly in the vicinity of the inner peripheral surface of the wall portion 212c toward the coil 226 inside the housing 212 (radially inward), and the flow straightening plate 286_b provided in the vicinity of the center of the housing 212 guides the gas in the vicinity of the center of the housing 212 toward the coil 226 (radially outward). The flow straightening plates 286_a1, 286_a2, 286_a3, and 286_b illustrated in FIG. 14B are examples, and the flow straightening plate 286 is not limited thereto. For example, a position where the flow straightening plate 286 is provided, and the shape, number, size, and the like of the flow straightening plate 286 may be configured otherwise. In addition, the flow straightening plate is formed of, for example, an insulator having a low dielectric constant and a low dielectric loss tangent, so that an influence on a resonance characteristic of the resonator 210 can be suppressed.

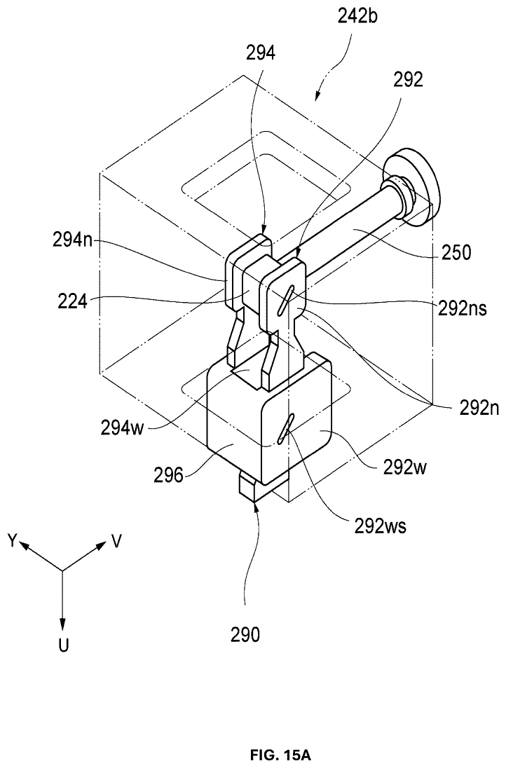

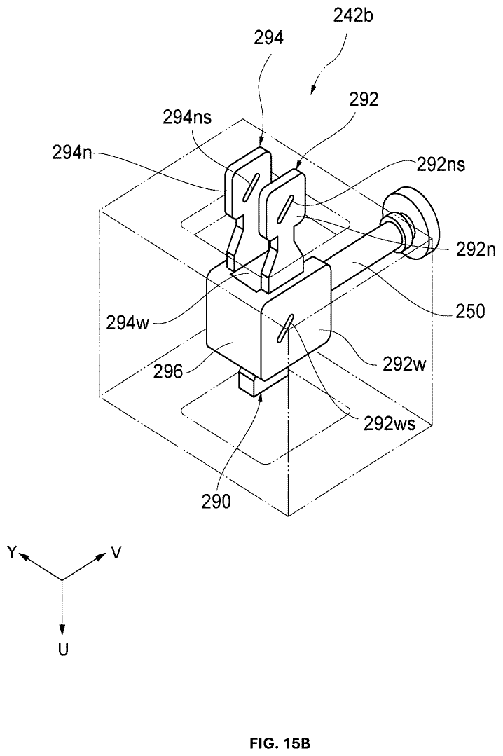

In the present embodiment, a distance between the resonator electrode 224 and a ground electrode 290 in the vacuum chamber 240 may be variable. FIGS. 15A and 15B schematically illustrate a configuration in which the distance (the size of the electrode gap) between the resonator electrode 224 and the ground electrode 290 can be changed. In such a configuration, a first ground electrode 292 may be provided upstream (−Y direction) of the resonator electrode 224 in the traveling direction (Y direction) of the ion beam, a second ground electrode 294 may be provided downstream (+Y direction) of the resonator electrode 224 in the traveling direction (Y direction) of the ion beam, and a distance between the resonator electrode 224 and the first ground electrode 292 and a distance between the resonator electrode 224 and the second ground electrode 294 may be changed while maintaining a relationship in which the distances are equal to each other. A configuration in which the distance between the resonator electrode 224 and the first ground electrode 292 and the distance between the resonator electrode 224 and the second ground electrode 294 can be changed while maintaining the relationship in which the distances are equal to each other is an example. In an embodiment, for example, the distance between the resonator electrode 224 and the first ground electrode 292 and the distance between the resonator electrode 224 and the second ground electrode 294 may be different from each other.

In the example illustrated in FIGS. 15A and 15B, the first ground electrode 292 and the second ground electrode 294 are configured to be simultaneously movable in the U direction. In the present embodiment, the first ground electrode 292 and the second ground electrode 294 are connected by a base member 296. Therefore, the first ground electrode 292 and the second ground electrode 294 are configured to be integrally movable in the U direction.

The first ground electrode 292 includes a first wide spacing portion 292w and a first narrow spacing portion 292n. The second ground electrode 294 includes a second wide spacing portion 294w and a second narrow spacing portion 294n. A distance between the first wide spacing portion 292w and the resonator electrode 224 (a distance of an electrode gap in the Y direction) is larger than a distance between the first narrow spacing portion 292n and the resonator electrode 224. A distance between the second wide spacing portion 294w and the resonator electrode 224 is larger than a distance between the second narrow spacing portion 294n and the resonator electrode 224.

The distance between the first wide spacing portion 292w and the resonator electrode 224 and the distance between the second wide spacing portion 294 w and the resonator electrode 224 may be, for example, 16 mm, and the distance between the first narrow spacing portion 292n and the resonator electrode 224 and the distance between the second narrow spacing portion 294n and the resonator electrode 224 may be, for example, 6 mm.

The first wide spacing portion 292w and the second wide spacing portion 294w are provided with a first slit (292ws illustrated in FIGS. 15A and 15B) and a second slit (not illustrated in FIGS. 15A and 15B), respectively. In addition, the first narrow spacing portion 292n and the second narrow spacing portion 294n are respectively provided with a first slit (292ns illustrated in FIGS. 15A and 15B) and a second slit (294ns illustrated in FIG. 15B). In a case where the first ground electrode 292 and the second ground electrode 294 are moved in the +U direction and disposed such that the first narrow spacing portion 292n of the first ground electrode and the second narrow spacing portion 294n of the second ground electrode are at positions facing the resonator electrode 224 (FIG. 15A), the ion beam passes through the first slit 292ns of the first narrow spacing portion 292n and the second slit 294ns of the second narrow spacing portion 294n. In addition, in a case where the first ground electrode 292 and the second ground electrode 294 are moved in the −U direction and disposed such that the first wide spacing portion 292w of the first ground electrode and the second wide spacing portion 294w of the second ground electrode are at positions facing the resonator electrode 224 (FIG. 15B), the ion beam passes through the first slit 292ws of the first wide spacing portion 292w and the second slit of the second wide spacing portion 294w.

For example, in a case where the first ground electrode 292 and the second ground electrode 294 are moved in the +U direction and disposed such that the first narrow spacing portion 292n of the first ground electrode and the second narrow spacing portion 294n of the second ground electrode are at positions facing the resonator electrode 224 (FIG. 15A), a gap between the first ground electrode 292 and the resonator electrode 224 and a gap between the second ground electrode 294 and the resonator electrode 224 can be decreased in size while maintaining a relationship in which the sizes of the electrode gaps are equal to each other. For example, in a case where heat generation increases due to collision of the ions with the first ground electrode 292 and the second ground electrode 294, and/or the resonator electrode 224, heat generation can be suppressed by moving the first ground electrode 292 and the second ground electrode 294 so as to decrease the sizes of the gap between the first ground electrode 292 and the resonator electrode 224 and the gap between the second ground electrode 294 and the resonator electrode 224. It is considered that, when the gap between the first ground electrode 292 and the resonator electrode 224 and the gap between the second ground electrode 294 and the resonator electrode 224 are widened, the ion beam spreads in the gap between the first ground electrode 292 and the resonator electrode 224 and the gap between the second ground electrode 294 and the resonator electrode 224, so that the ions colliding with the first ground electrode 292 and the second ground electrode 294, and/or the resonator electrode 224 increase, and heat generation increases. On the other hand, it is considered that, when the sizes of the gap between the first ground electrode 292 and the resonator electrode 224 and the gap between the second ground electrode 294 and the resonator electrode 224 are decreased, collision of the ions with each electrode can be reduced, and heat generation can be suppressed.

In the ion implanter 100 according to the present embodiment, the resonator electrode 224 containing graphite as a material may be used as the resonator electrode 224.

By forming the resonator electrode 224 using a material containing graphite, for example, even in a case where the resonator electrode 224 is excessively irradiated with the ion beam and the temperature becomes high, the occurrence of melting of the resonator electrode 224 can be suppressed. Further, since graphite exhibits less thermal expansion at a high temperature than that of aluminum, the formation of the resonator electrode 224 using a material containing graphite results in a smaller change in resonant frequency at a high temperature as compared with a case where the resonator electrode 224 is formed of, for example, copper or aluminum.

Note that graphite has a higher electric resistance than that of, for example, copper or aluminum, and therefore when a large amount of radio-frequency current flows, it may be difficult to use graphite as a material of the electrode. As in the resonator 210 according to the present embodiment, for example, in a case where an applied voltage is relatively low (for example, about 10 kV), such as a case of use for the purpose of bunching the ion beam, a material having a relatively high electric resistance can be used as the material of the electrode, and for example, it becomes relatively easy to use the resonator electrode 224 formed using a material containing graphite. As described above, in the resonator electrode 224 of the resonator 210 used for the bunching of the ion beam, graphite can be effectively used as the material of the resonator electrode 224 from the viewpoint of high heat resistance and less thermal expansion.

In the ion implanter 100 according to the embodiment of the present disclosure, a frequency f (the resonant frequency of the resonator 210) of a radio-frequency wave applied by the radio-frequency power supply is, for example, 13.56 MHz. At this time, a wavelength λ of the radio-frequency wave in a vacuum is about 22.11 m based on a speed of light c and the frequency f. The frequency of the radio-frequency wave may be 27.12 MHz that is twice the frequency f=13.56 MHz or 54.24 MHz that is 4 times the frequency f, and in these cases, the wavelengths λ of the radio-frequency wave are about 11.054 m and about 5.527 m, respectively.

In the present embodiment, power consumption of the resonator 210 is, for example, 1 W or more and 1 kW or less, preferably 2 W or more and 600 W or less, more preferably 5 W or more and 300 W or less, and still more preferably 10 W or more and 150 W or less.

In the present embodiment, heat input from the radio-frequency power supply into the housing 212 may be, for example, 1 W or more and 1 kW or less. For example, the heat input from the radio-frequency power supply into the housing 212 is preferably 2 W or more and 600 W or less, more preferably 5 W or more and 300 W or less, and still more preferably 10 W or more and 150 W or less.

As described above, in the present embodiment, the frequency f (the resonant frequency of the resonator 210) of the radio-frequency wave applied by the radio-frequency power supply may be, for example, 13.56 MHz, 27.12 MHz, or 2.45 GHz.

In the present embodiment, the power consumption in the resonator 210 may be 1 W or more and 150 W or less, 1 W or more and 300 W or less, or 1 W or more and 3000 W or less.

In the present embodiment, a voltage of the resonator electrode 224 may be 1 kV or more and 10 kV or less, 1 kV or more and 15 kV or less, or 1 kV or more and 45 kV or less.

In the present embodiment, the heat input from the resonator electrode 224 to the housing 212 through the stem 250, the stem head 228, the coil 226, and the like may be 0 W or more and 100 W or less, 0 W or more and 200 W or less, or 0 W or more and 2000 W or less.

In the present embodiment, an aspect ratio of the long side to the short side of the opening (for example, the plurality of rectangular opening portions 264_c1, 264_c2, 264_c3, 264_c4, 264_c5, 264_c6, 264_c7, and 264_c8 each having long sides and short sides) may be 2 or less, 5 or less, or 10 or less.

Further, in the present embodiment, for example, in a case where the resonant frequency is 2.45 GHz, the lengths of the short side and the long side of each of the plurality of rectangular openings (opening portions 264_c1, 264_c2, 264_c3, 264_c4, 264_c5, 264_c6, 264_c7, and 264_c8) may be 20 mm or less and 200 mm or less, respectively, and the area of each opening may be 4,000 mm² or less.

In the present embodiment, in a case where the frequency f of the radio-frequency wave applied by the radio-frequency power supply is, for example, 27.12 MHz, the lengths of the short side and the long side of the opening (for example, the plurality of rectangular openings (opening portions 264_c1, 264_c2, 264_c3, 264_c4, 264_c5, 264_c6, 264_c7, and 264_c8) having long sides and short sides) may be 10 mm or less and 100 mm or less, respectively, and the area of each opening may be 1,000 mm² or less.

In the present embodiment, in a case where the frequency f of the radio-frequency wave applied by the radio-frequency power supply is, for example, 2.45 GHz, the lengths of the short side and the long side of the opening (for example, the plurality of rectangular openings (opening portions 264_c1, 264_c2, 264_c3, 264_c4, 264_c5, 264_c6, 264_c7, and 264_c8) having long sides and short sides) may be 5 mm or less and 50 mm or less, respectively, and the area of each opening may be 250 mm² or less.

As illustrated above, even in a case where the frequency of the radio-frequency wave applied by the radio-frequency power supply varies, the inside of the housing 212 can be effectively cooled by appropriately changing the power consumption in the resonator 210, the voltage, the size of the opening, and the like.

The frequency f of the radio-frequency wave, the power consumption in the resonator 210, the voltage of the resonator electrode 224, the heat input from the resonator electrode 224 into the housing 212, the lengths of the short side and the long side of the opening, the aspect ratio, and the area are examples, and the ion implanter 100 according to the embodiment of the present disclosure is not limited thereto.

According to the present disclosure, it is possible to provide a technology that enables a resonator to have a simpler configuration.

The embodiment described above is intended to facilitate understanding of the present invention, and is not intended to limit the present invention. Each element included in the embodiment and the arrangement, material, condition, shape, size, and the like thereof are not limited to those exemplified, and can be appropriately changed. In addition, the calculation method, the numerical range, and the like described in the above-described embodiments are not limited to those exemplified. In addition, it is possible to partially replace or combine the configurations described in different embodiments.

What is claimed is:

1. An ion implanter comprising:
a linear acceleration unit that adjusts energy of ions, wherein
the linear acceleration unit includes a plurality of resonators,
each of the plurality of resonators includes:
an electrode for generating a radio-frequency electric field, the electrode being configured to accelerate or decelerate the ions by generating the radio-frequency electric field;
a coil;
a stem that connects the electrode and the coil; and
a housing that surrounds the coil, and
at least one of the plurality of resonators is configured, such that a gas for cooling at least the coil is present inside the housing, and has a configuration for generating a flow of the gas for promoting the cooling of at least the coil in a vicinity of the coil.

2. The ion implanter according to claim 1, wherein the configuration for generating the flow of the gas generates the flow of the gas inside the housing by causing the gas to flow into an inside of the housing from an outside of the housing, and causing the gas to flow out from the inside of the housing to the outside of the housing.

3. The ion implanter according to claim 2, wherein
the configuration for generating the flow of the gas includes a plurality of openings provided in the housing, and
the plurality of openings include a first opening and a second opening that is positioned vertically above the first opening in a use state.

4. The ion implanter according to claim 3, wherein the configuration for generating the flow of the gas includes at least one of:
a first airflow generation mechanism that is provided in the first opening and promotes the generation of the flow of the gas flowing into the inside of the housing through the first opening and flowing out to the outside of the housing through the second opening, and
a second airflow generation mechanism that is provided in the second opening and promotes the generation of the flow of the gas flowing into the inside of the housing through the first opening and flowing out to the outside of the housing through the second opening.

5. The ion implanter according to claim 3, wherein
the housing includes a lid portion, a bottom portion, and a wall portion coupling the lid portion and the bottom portion,
the first opening is provided in the bottom portion, and
the second opening is provided in the wall portion and/or the lid portion.

6. The ion implanter according to claim 3, wherein
the housing includes a lid portion, a bottom portion, and a wall portion coupling the lid portion and the bottom portion,
the first opening is provided in the wall portion, and
the second opening is provided in the lid portion.

7. The ion implanter according to claim 3, wherein
the housing includes a lid portion, a bottom portion, and a wall portion coupling the lid portion and the bottom portion, and
the first opening and the second opening are provided in the wall portion.

8. The ion implanter according to claim 3, wherein
the housing has a cylindrical shape including a lid portion, a bottom portion, and a wall portion coupling the lid portion and the bottom portion,
the plurality of openings are arranged in an axial direction and a circumferential direction of the cylindrical shape, and
the openings adjacent to each other in the circumferential direction are provided so as to be offset from each other in the axial direction, or the openings adjacent to each other in the axial direction are provided so as to be offset from each other in the circumferential direction.

9. The ion implanter according to claim 3, wherein
the housing has a cylindrical shape including a lid portion, a bottom portion, and a wall portion coupling the lid portion and the bottom portion, and
the plurality of openings each have an elongated shape extending in parallel with an axial direction of the cylindrical shape.

10. The ion implanter according to claim 9, wherein the plurality of openings is configured to be able to shield an electromagnetic wave in such a way that emission of the electromagnetic wave from the coil to the outside of the housing is suppressed.

11. The ion implanter according to claim 10, wherein
the plurality of openings each have a rectangular shape having long sides and short sides, and
when a wavelength of the electromagnetic wave emitted from the coil is λ,
an area of each of the plurality of openings is (λ/10,000)² or more and (λ/100)² or less,
a length of the long side is λ/10,000 or more and λ/100 or less,
a length of the short side is λ/10,000 or more and λ/100 or less, and
a ratio of the length of the short side to the length of the long side is 1/1,000 or more and ½ or less.

12. The ion implanter according to claim 10, wherein
the plurality of openings each have a rectangular shape having long sides and short sides,
an area of each of the plurality of openings is 0.2 mm² or more and 40,000 mm² or less,
a length of the long side is 0.5 mm or more and 200 mm or less, and
a length of the short side is 0.5 mm or more and 200 mm or less.

13. The ion implanter according to claim 1, wherein a heat dissipation portion that increases a surface area exposed to the gas so as to promote heat release to the gas is provided inside the housing.

14. The ion implanter according to claim 13, wherein an air cooler configured to blow, to the heat dissipation portion, cold air for cooling the heat dissipation portion is provided outside the housing.

15. The ion implanter according to claim 13, wherein
a stem head is attached to a connection portion of the stem connected to the coil, and
the heat dissipation portion includes a heat sink provided on the stem head.

16. The ion implanter according to claim 13, wherein the heat dissipation portion includes a fin.

17. The ion implanter according to claim 1, wherein the electrode contains graphite.

18. The ion implanter according to claim 1, wherein the gas contains at least one of hydrogen, helium, and air.

19. The ion implanter according to claim 4, wherein the gas flowing out to the outside of the housing through the second opening has a temperature higher than that of the gas flowing into the inside of the housing through the first opening.

20. The ion implanter according to claim 2, wherein
the configuration for generating the flow of the gas includes a plurality of openings provided in the housing and at least one fan,
the plurality of openings include a third opening and a fourth opening, and
the at least one fan includes at least one of:
a third fan that is provided in the third opening and promotes the generation of the flow of the gas flowing into the inside of the housing through the third opening and flowing out to the outside of the housing through the fourth opening, and
a fourth fan that is provided in the fourth opening and promotes the generation of the flow of the gas flowing into the inside of the housing through the third opening and flowing out to the outside of the housing through the fourth opening.

21. The ion implanter according to claim 1, wherein the configuration for generating the flow of the gas generates convection of the gas inside the housing so as to circulate the gas inside the housing.

22. The ion implanter according to claim 21, wherein an internal circulation fan that circulates the gas inside the housing is provided inside the housing.

23. The ion implanter according to claim 22, wherein
the housing includes a lid portion, a bottom portion, and a wall portion coupling the lid portion and the bottom portion,
the lid portion is provided with a pipe portion protruding in a direction away from the wall portion,
the pipe portion is connected to the lid portion through a first connection portion through which the gas flows into the pipe portion from the housing and a second connection portion through which the gas flows into the housing from the pipe portion, and
the internal circulation fan is provided inside the pipe portion, and is configured to form an internal circulation path through which the gas flows into the pipe portion from the first connection portion and flows out from the second connection portion.

24. The ion implanter according to claim 23, wherein
the pipe portion includes a plurality of pipe structures, and
the internal circulation fan is configured to form the internal circulation path in each of the plurality of pipe structures.

25. The ion implanter according to claim 1, wherein a flow straightening plate that controls a direction of the flow of the gas is provided inside the housing.

26. The ion implanter according to claim 1, wherein
a first ground electrode is provided upstream of the electrode in a traveling direction of a beam of the ions,
a second ground electrode is provided downstream of the electrode in the traveling direction of the beam of the ions, and
at least one of a distance between the electrode and the first ground electrode and a distance between the electrode and the second ground electrode is variable.

27. The ion implanter according to claim 1, wherein a resonant frequency of the radio-frequency electric field in a resonant state is 13.56 MHz.

28. The ion implanter according to claim 1, wherein
input power supplied to the resonator is 1 W or more and 3 kW or less, and
an output voltage generated to the electrode is 1 kV or more and 45 kV or less.
